(19) United States
(12) Patent Application Publication
(10) Pub. No.: US 2026/0371557 A1
(43) Pub. Date: Nov. 19, 2026

(54) SEMICONDUCTOR DEVICE INCLUDING VERTICAL CHANNEL TRANSISTOR

(71) Applicant: Samsung Electronics Co., Ltd., Suwon-si (KR)

(72) Inventors: Taehyuk Kim, Suwon-si (KR); Suklae Kim, Suwon-si (KR); Uijin Kim, Suwon-si (KR); Taejin Park, Suwon-si (KR); Jungwoo Song, Suwon-si (KR)

(73) Assignee: Samsung Electronics Co., Ltd., Suwon-si (KR)

(21) Appl. No.: 19/633,930

(22) Filed: Mar. 30, 2026

(30) Foreign Application Priority Data
May 19, 2025 (KR) 10-2025-0064728

(51) Int. Cl. H10B 12/00; H10B 80/00; H10D 30/67; H10D 80/30; H10W 20/41; H10W 20/47; H10W 20/48; H10W 90/00

(52) U.S. Cl. CPC H10B 12/315; H10B 12/482; H10B 12/488; H10D 30/6728; H10D 30/6733; H10D 30/6735; H10W 20/435; H10W 20/47; H10W 20/48; H10B 12/0335; H10B 80/00; H10D 80/30; H10W 90/792

(57) ABSTRACT

Provided is a semiconductor device, the semiconductor device including a bit line, a channel layer on the bit line, a contact plug disposed on the channel layer and electrically connected to the channel layer, a spacer structure provided on a sidewall of the contact plug and surrounding the contact plug, and a capacitor electrically connected to the contact plug, wherein the spacer structure includes a middle spacer and an inner spacer disposed sequentially on the sidewall of the contact plug, the contact plug includes a first conductive pattern including a semiconductor material, a second conductive pattern disposed on the first conductive pattern and including a metal-based material, and a third conductive pattern disposed on the second conductive pattern and including a metal-based material, and the first conductive pattern is spaced apart from the inner spacer with the middle spacer therebetween.

### CROSS-REFERENCE TO RELATED APPLICATIONS

This present application claims priority to and the benefit under 35 U.S.C. § 119(a)-(d) of Korean Patent Application No. 10-2025-0064728, filed on May 19, 2025, in the Korean Intellectual Property Office, the entire disclosure of which is incorporated herein by reference.

### FIELD

The disclosed concepts relate to a semiconductor device. More specifically, the disclosed concepts relate to a semiconductor device including a vertical channel transistor.

### BACKGROUND

As memory devices become more highly integrated, semiconductor devices in the memory devices also become more highly integrated. Therefore, in order to highly integrate semiconductor devices, vertical channel transistors formed vertically on a semiconductor substrate have been used instead of planar channel transistors formed horizontally on a semiconductor substrate.

### SUMMARY

According to aspects of the disclosed concepts, there is provided a semiconductor device including a bit line, a channel layer on the bit line, a contact plug disposed on the channel layer and electrically connected to the channel layer, a spacer structure provided on a sidewall of the contact plug and surrounding the contact plug, and a capacitor electrically connected to the contact plug, wherein the spacer structure includes a middle spacer and an inner spacer disposed sequentially on the sidewall of the contact plug, the contact plug includes a first conductive pattern including a semiconductor material, a second conductive pattern disposed on the first conductive pattern and including a metal-based material, and a third conductive pattern disposed on the second conductive pattern and including a metal-based material, and the first conductive pattern is spaced apart from the inner spacer with the middle spacer therebetween.

According to aspects of the disclosed concepts, there is provided a semiconductor device including a bit line, a channel layer on the bit line, a contact plug disposed on the channel layer and electrically connected to the channel layer, a spacer structure provided on a sidewall of the contact plug and surrounding the contact plug, and a capacitor electrically connected to the contact plug, wherein the spacer structure includes an outer spacer and an inner spacer disposed sequentially on the sidewall of the contact plug, the contact plug is spaced apart from the inner spacer with the outer spacer therebetween, the outer spacer includes a first sub-spacer disposed on the channel layer, and a second sub-spacer disposed on the first sub-spacer, and the first sub-spacer includes a different material from a material of the second sub-spacer.

According to aspects of the disclosed concepts, there is provided a semiconductor device including a bit line extending in a first substantially horizontal direction, a word line provided above the bit line and extending in a second substantially horizontal direction intersecting the first substantially horizontal direction, a back gate line provided above the bit line, extending in the second substantially horizontal direction, and spaced apart from the word line in the first substantially horizontal direction, a channel layer extending in a substantially vertical direction, and arranged between the word line and the back gate line such that the channel layer is adjacent to the word line and the back gate line in the first substantially horizontal direction, a contact plug disposed on the channel layer and electrically connected to the channel layer, and a spacer structure provided on a sidewall of the contact plug, and surrounding the contact plug in the first horizontal direction, wherein the spacer structure includes an outer spacer, a middle spacer and an inner spacer, sequentially stacked on the sidewall of the contact plug in the first substantially horizontal direction.

According to aspects of the disclosed concepts, there is provided a method of manufacturing a semiconductor device, the method including providing a channel structure and forming a first conductive pattern on the channel structure, forming a contact plug sacrificial pattern on the first conductive pattern, forming an outer spacer by nitridation of surfaces of the first conductive pattern and the contact plug sacrificial pattern, forming a middle spacer on the outer spacer, forming an inner spacer on the middle spacer, and removing the contact plug sacrificial pattern and forming a second conductive pattern and a third conductive pattern in a space from which the contact plug sacrificial pattern has been removed, thereby forming a contact plug that includes the first conductive pattern, the second conductive pattern, and the third conductive pattern.

In embodiments, the first conductive pattern may include doped polysilicon, and the contact plug sacrificial pattern may include an oxide layer.

In embodiments, in the forming of the outer spacer, the outer spacer may include a first sub-spacer covering a surface of the first conductive pattern and a second sub-spacer covering a surface of the contact plug sacrificial pattern, wherein the first sub-spacer includes a different material from the second sub-spacer.

In embodiments, in the forming of the outer spacer, the nitridation may be performed by using plasma.

In embodiments, in the forming of the middle spacer, the middle spacer may be formed by using a chemical vapor deposition (CVD) process, a plasma enhanced chemical vapor deposition (PECVD) process, or an atomic layer deposition (ALD) process.

In embodiments, in the forming of the middle spacer, the middle spacer may include any one of silicon carbonitride, silicon oxynitride, silicon oxycarbonitride, and silicon nitride.

In embodiments, in the forming of the inner spacer, the inner spacer may include a same material as a material of the middle spacer but has a different composition ratio from that of the middle spacer, or may include a different material from the material of the middle spacer.

In embodiments, in the forming of the inner spacer, the inner spacer may include a same material as the material of middle spacer, and the inner spacer may contain less nitrogen than that of the middle spacer.

In embodiments, the second conductive pattern may include a metal silicide layer, and the third conductive pattern may include a metal layer.

In embodiments, the method may further comprise, after the forming of the contact plug, forming a capacitor on the contact plug.

### BRIEF DESCRIPTION OF THE DRAWINGS

Embodiments will be more clearly understood from the following detailed description taken in conjunction with the accompanying drawings in which:

FIG. 1 is a block diagram of a semiconductor device according to embodiments;

FIG. 2 is a perspective view schematically showing a semiconductor device according to embodiments;

FIG. 3 is a plan view showing a semiconductor device according to embodiments;

FIG. 4 is a cross-sectional view of a semiconductor device taken along line IIIA-IIIA′ of FIG. 3;

FIG. 5 is an enlarged view of region “EX1” of FIG. 4;

FIGS. 6A to 6C are diagrams showing semiconductor devices according to some embodiments;

FIG. 7 is a diagram showing a semiconductor device according to embodiments;

FIG. 8 is a diagram showing a semiconductor device according to embodiments;

FIG. 9 is a schematic perspective view illustrating a semiconductor device according to embodiments;

FIG. 10 is a diagram showing a semiconductor device according to embodiments;

FIG. 11 is a diagram showing a semiconductor device according to embodiments; and

FIGS. 12 to 20 are diagrams illustrating a process of manufacturing a semiconductor device, according to embodiments.

### DETAILED DESCRIPTION

Hereinafter, embodiments are described in detail with reference to the accompanying drawings. The same reference numerals are given to the same elements in the drawings, and repeated descriptions thereof are omitted.

As used herein, horizontal directions may include a first horizontal direction (an X direction) and a second horizontal direction (a Y direction) that intersect each other. A direction intersecting both the first horizontal direction (the X direction) and the second horizontal direction (the Y direction) may be referred to as a vertical direction (a Z direction). As used herein, the vertical level of a component may be referred to as a height level of the component in the vertical direction (the Z direction).

The disclosed concepts provide a semiconductor device including a vertical channel transistor having improved operational reliability.

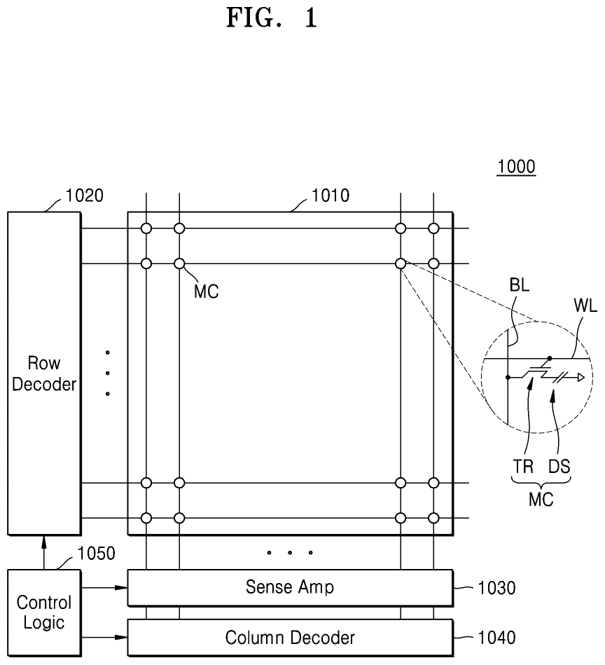

FIG. 1 is a block diagram of a semiconductor device 1000 according to embodiments.

Specifically, in some embodiments, the semiconductor device 1000 shown in FIG. 1 may represent a memory device. In some embodiments, the semiconductor device 1000 shown in FIG. 1 may include a dynamic random-access memory (DRAM) device. The semiconductor device 1000 may include a memory cell array 1010, a row decoder 1020, a sense amplifier 1030, a column decoder 1040, and a control logic 1050. The memory cell array 1010 may include a plurality of memory cells MC arranged in two dimensions or three dimensions.

Each of the plurality of memory cells MC may be connected between a word line WL and a bit line BL that intersect each other. Each of the plurality of memory cells MC may include a selection element TR and a data storage element DS. The selection element TR may be electrically connected in series to the data storage element DS.

The selection element TR may be connected between the data storage element DS and the word line WL. The data storage element DS may be connected to the bit line BL via the selection element TR. The selection element TR may include a transistor.

The selection element TR may include a vertical channel transistor (VCT). The selection element TR may include a field effect transistor (FET). The data storage element DS may be formed as a capacitor.

For example, a gate electrode of the transistor may be connected to the word line WL, and drain/source terminals of the transistor may be connected to the bit line BL and the data storage element DS, respectively.

The row decoder 1020 may decode an address input from the outside and select one of word lines WL of the memory cell array 1010. The address decoded by the row decoder 1020 may be provided to a sub-word line driver, and the sub-word line driver may respectively provide certain voltages to the selected word line WL and non-selected word lines WL in response to control by control circuits.

The sense amplifier 1030 may sense, amplify, and output a difference in voltage between a reference bit line and a bit line BL selected based on the address decoded by the column decoder 1040.

The column decoder 1040 may provide a data transmission path between the sense amplifier 1030 and an external device (e.g., a memory controller). The column decoder 1040 may decode an address input from the outside and select any one of bit lines BL.

The control logic 1050 may generate control signals for controlling operations of writing or reading data to or from the memory cell array 1010.

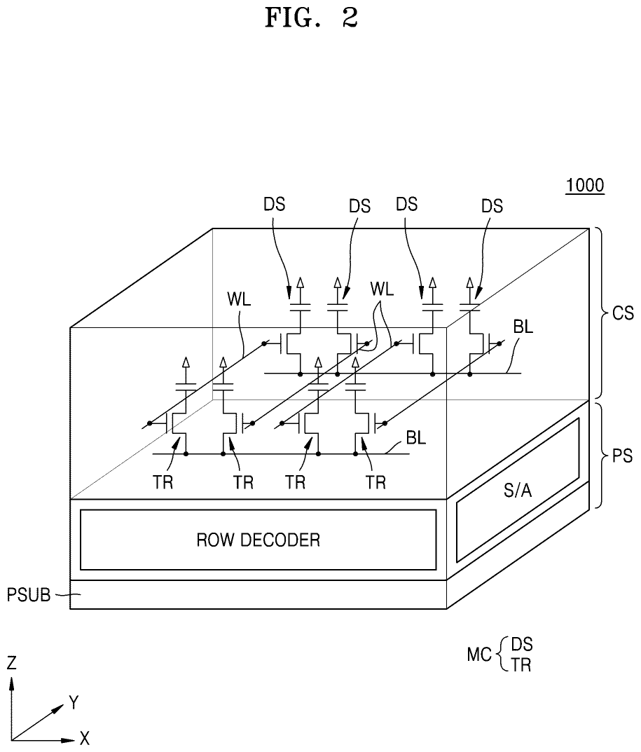

FIG. 2 is a perspective view schematically showing the semiconductor device 1000 according to embodiments.

The semiconductor device 1000 may include a peripheral circuit structure PS including a peripheral circuit substrate PSUB and a cell array structure CS disposed on the peripheral circuit structure PS. The cell array structure CS may be bonded to the peripheral circuit structure PS such that the cell array structure CS is stacked on the peripheral circuit structure PS.

The peripheral circuit structure PS may include a core and peripheral circuits formed on the peripheral circuit substrate PSUB. The core and the peripheral circuits may include the row decoder 1020, the sense amplifier 1030, the column decoder 1040, and the control logic 1050, which are described above with reference to FIG. 1. FIG. 2 shows examples of a row decoder and a sense amplifier among the core and the peripheral circuits in the peripheral circuit structure PS. FIG. 2 shows that the peripheral circuit substrate PSUB is located in the peripheral circuit structure PS on the side opposite the cell array structure CS in the vertical direction (the Z direction), but this is only an example. The embodiments are not limited thereto. In some embodiments, the peripheral circuit substrate PSUB may be located in the peripheral circuit structure PS on the side facing the cell array structure CS in the vertical direction (the Z direction).

The cell array structure CS may include bit lines BL, word lines WL, and memory cells MC therebetween. The memory cells MC may be arranged in two or three dimensions on a plane extending in the first horizontal direction (the X direction) and the second horizontal direction (the Y direction) that intersect each other and may thus form the memory cell array 1010 (FIG. 1). The bit lines BL may extend in the first horizontal direction (the X direction) and the word lines WL may extend in the second horizontal direction (the Y direction). Each of the memory cells MC may include the selection element TR and the data storage element DS.

As used herein, a bit line direction may represent the first horizontal direction (the X direction). A word line direction may represent the second horizontal direction (the Y direction). A direction perpendicular to the peripheral circuit substrate PSUB may represent the vertical direction. The direction perpendicular to the plane extending in the first horizontal direction (the X direction) and the second horizontal direction (the Y direction) may represent the vertical direction (the Z direction).

Each of the memory cells MC (FIG. 1) may include the selection element TR and the data storage element DS as described above. Each of the memory cells MC (FIG. 1) may include a VCT as the selection element TR. The VCT may represent a structure in which a channel length extends in the vertical direction (the Z direction). The VCT that constitutes the plurality of memory cells MC (FIG. 1) may include a pair of channel layers, a pair of gate insulating layers, and a pair of word lines, which are described below. Each of the plurality of memory cells MC (FIG. 1) may include a capacitor as a plurality of data storage elements DS.

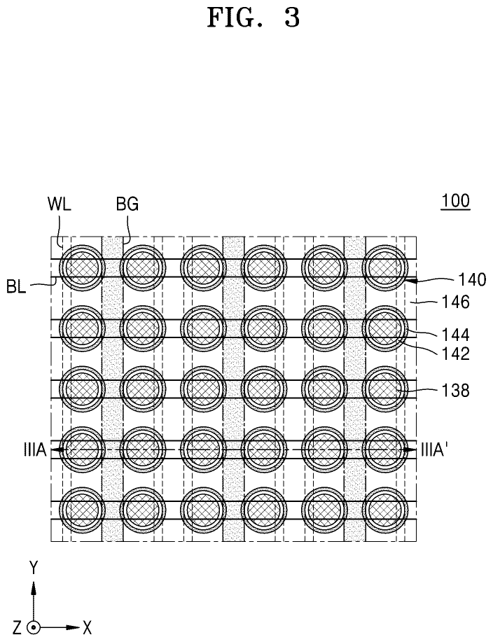

FIG. 3 is a plan view showing a semiconductor device 100 according to embodiments.

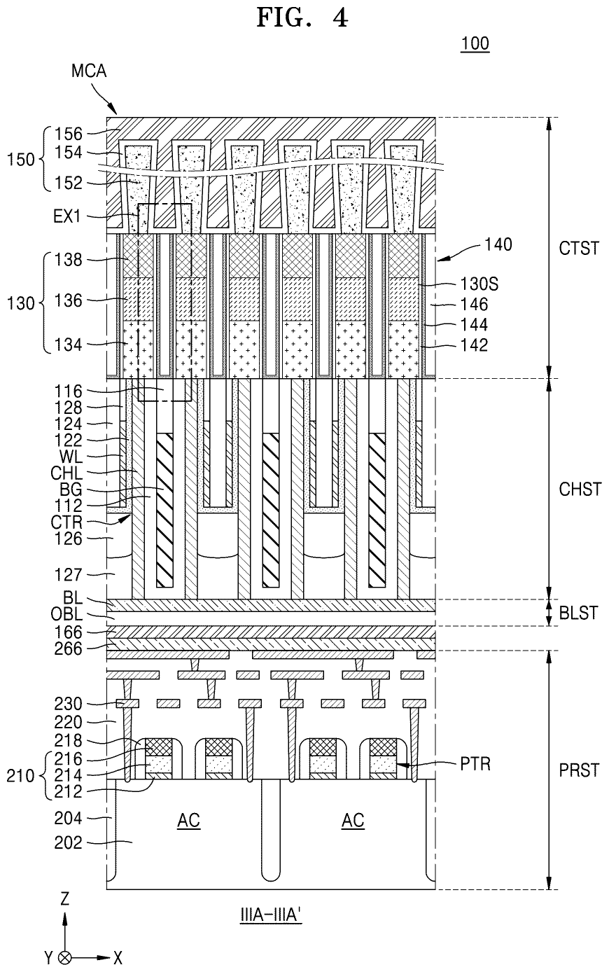

FIG. 4 is a cross-sectional view of the semiconductor device 100 taken along line IIA-IIA′ of FIG. 3.

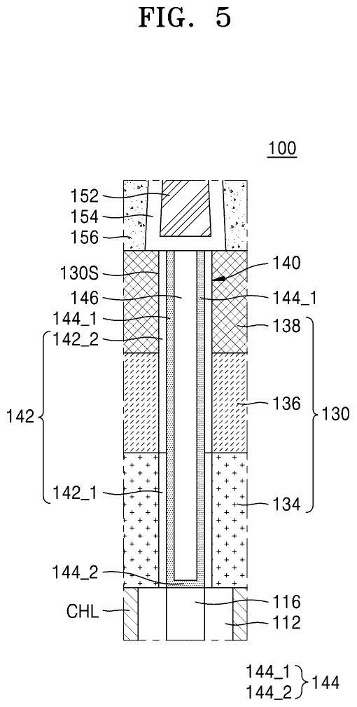

FIG. 5 is an enlarged view of region “EX1” of FIG. 4.

Referring to FIGS. 3 to 5, the semiconductor device 100 may include a peripheral circuit structure PRST and a memory cell array structure MCA in which a plurality of memory cells are arranged. For example, the plurality of memory cells may include a plurality of VCTs CTR. The memory cell array structure MCA may be formed by stacking a bit line structure BLST, a channel structure CHST, and a capacitor structure CTST. The peripheral circuit structure PRST may include a peripheral circuit transistors PTR that include a circuit gate structure 210. The peripheral circuit transistor PTR may be configured to transmit signals and/or power to the plurality of memory cells in the memory cell array structure MCA. For example, the peripheral circuit transistor PTR may constitute various circuits, such as a command decoder, control logic, an address buffer, a row decoder, a column decoder, a sense amplifier, and a data input/output circuit.

In some embodiments, the semiconductor device 100 may have a cell on periphery (CoP) structure in which the memory cell array structure MCA and the peripheral circuit structure PRST overlap each other in the vertical direction (the Z direction). In some embodiments, the semiconductor device 100 may not include the peripheral circuit structure PRST and may include a peripheral circuit region that surrounds the memory cell array structure MCA in a plan view. The peripheral circuit region may represent a region in which the peripheral circuit transistor PTR is formed.

In some embodiments, in the semiconductor device 100, the bit line structure BLST, the channel structure CHST, and the capacitor structure CTST may be sequentially stacked in the vertical direction (the Z direction) above the peripheral circuit structure PRST.

The bit line structure BLST may include a bit line BL and a bit line insulating layer OBL covering the bit line BL. Referring to FIG. 2 together, the plurality of bit lines BL may extend lengthwise in the first horizontal direction (the X direction) and may be repeatedly arranged and spaced apart from each other in the second horizontal direction (the Y direction) intersecting the first horizontal direction (the X direction). The bit line insulating layer OBL may completely fill the spaces between the plurality of bit lines BL and cover the lower surfaces of the plurality of bit lines BL.

In embodiments, the bit line BL may include a conductive material. In some embodiments, the bit line BL may have a stack structure including a first line pattern, a second line pattern, and a third line pattern. For example, the first line pattern may include a semiconductor material, and the second line pattern and the third line pattern may each include a metal-based material. The second line pattern and the third line pattern may include different types of metal-based materials. For example, the first line pattern may include doped polysilicon. For example, the second line pattern may include titanium nitride (TiN) or TSN (Ti—Si—N), and the third line pattern may include tungsten (W) or tungsten silicide (WSix). In embodiments, the bit line insulating layer OBL may include silicon oxide, silicon nitride, or a combination thereof.

The channel structure CHST may include a plurality of channel layers CHL, a plurality of back gate electrodes BG, and a plurality of word lines WL. Each of the plurality of channel layers CHL may extend in the vertical direction (the Z direction). Referring to FIG. 2 together, the plurality of word lines WL may be spaced apart from each other in the first horizontal direction (the X direction) and may each extend lengthwise in the second horizontal direction (the Y direction). The plurality of back gate electrodes BG may be spaced apart from each other in the first horizontal direction (the X direction) and may each extend lengthwise in the second horizontal direction (the Y direction) in which the plurality of word lines WL extend.

According to embodiments, the plurality of channel layers CHL may be repeatedly arranged on the plurality of bit lines BL and spaced apart from each other in the first horizontal direction (the X direction) and the second horizontal direction (the Y direction). The channel layer CHL may extend in the vertical direction (the Z direction) between one selected from among the plurality of bit lines BL and one selected from among a plurality of contact plugs 130. The channel layer CHL may include a first end and a second end that are opposite each other in the vertical direction (the Z direction). In the channel layer CHL, the first end may be connected to one contact plug 130 selected from among the plurality of contact plugs 130, and the second end may be connected to one bit line BL selected from among the plurality of bit lines BL. In some embodiments, the channel layer CHL may include a conductive region, for example, a well doped with impurities or a structure doped with impurities. Although not shown, an impurity region functioning as a source/drain region may be formed on each of the first end and the second end.

In some embodiments, the channel layer CHL may include a semiconductor material. For example, the channel layer CHL may include single crystalline silicon, polycrystalline silicon, or amorphous silicon. In some embodiments, the channel layer CHL may include at least one selected from a group consisting of Ge, SiGe, SiC, GaAs, InAs, and InP. In some embodiments, the channel layer CHL may include an oxide semiconductor material. The channel layer CHL may include at least one of a binary or ternary oxide semiconductor material including a first metal element, a ternary oxide semiconductor material including a first metal element and a second metal element different from each other, and a quaternary oxide semiconductor material including a first metal element, a second metal element, and a third metal element different from each other.

The binary or ternary oxide semiconductor material may include, but is not limited to, for example, any one of zinc oxide (ZnO, ZnₓO), gallium oxide (GaO, GaₓO), tin oxide (TiO, TiₓO), zinc oxynitride (ZnON, ZnₓO_{y}N), indium zinc oxide (IZO, InₓZn_{y}O), gallium zinc oxide (GZO, GaₓZn_{y}O), tin zinc oxide (TZO, SnₓZn_{y}O), and tin gallium oxide (TGO, SnₓGa_{y}O). The quaternary oxide semiconductor material may include, but is not limited to, for example, indium gallium zinc oxide (IGZO, InₓGa_{y}Zn_{z}O), indium gallium silicon oxide (IGSO, InₓGa_{y}Si_{z}O), indium tin zinc oxide (ITZO, InₓSn_{y}Zn_{z}O), indium gallium tin oxide (IGTO, InₓGa_{y}Sn_{z}O), zirconium zinc tin oxide (ZZTO, ZrₓZn_{y}Sn_{z}O), hafnium indium zinc oxide (HIZO, HfₓIn_{Y}Zn_{z}O), gallium zinc tin oxide (GZTO, GaₓZn_{y}Sn_{z}O), aluminum zinc tin oxide (AZTO, AlₓZn_{y}Sn_{z}O), ytterbium gallium zinc oxide (YGZO, YbₓGa_{Y}Zn_{z}O), and indium aluminum zinc oxide (IAZO).

In some embodiments, the channel layer CHL may include a crystalline oxide semiconductor material or an amorphous oxide semiconductor material. When the channel layer CHL includes the crystalline oxide semiconductor material, the channel layer CHL may have at least one of single crystalline, polycrystalline, spinel, and c-axis aligned crystalline (CAAC) structures. In some embodiments, the channel layer CHL may be formed by stacking at least two layers that include a first layer containing the crystalline oxide semiconductor material and a second layer containing the amorphous oxide semiconductor material. For example, the channel layer CHL may be formed by sequentially stacking a first layer containing the crystalline oxide semiconductor material, a second layer containing the amorphous oxide semiconductor material, and a third layer containing the crystalline oxide semiconductor material.

The plurality of back gate electrodes BG and the plurality of word lines WL may be arranged between the bit line BL and the plurality of contact plugs 130. One channel layer CHL may be located between one back gate electrode BG and one word line WL that are adjacent to each other in the first horizontal direction (the X direction). For example, one side of the channel layer CHL in the first horizontal direction (the X direction) may face one back gate electrode BG, and the other side thereof may face one word line WL.

According to embodiments, a pair of channel layers CHL may be respectively arranged on both sides of the back gate electrode BG in the first horizontal direction (the X direction), and a pair of word lines WL may be respectively spaced apart from both sides of the back gate electrode BG in the first horizontal direction (the X direction) with the pair of channel layers CHL therebetween. In other words, the pair of channel layers CHL and the pair of word lines WL may be sequentially arranged on both sidewalls of the back gate electrode BG in the first horizontal direction (the X direction). A gate dielectric layer 122 may be located between the channel layer CHL and the word line WL. A pair of word lines WL may be arranged between a pair of adjacent channel layers CHL, and an isolation insulating pattern 124 may be arranged between a pair of adjacent word lines WL. The gate dielectric layer 122 may extend between the channel layer CHL and the word line WL and cover the lower surfaces of the pair of word lines WL and the lower surface of the isolation insulating pattern 124.

In some embodiments, each of the plurality of back gate electrodes BG may include metal, conductive metal nitride, doped polysilicon, or a combination thereof. For example, each of the plurality of back gate electrodes BG may include, but is not limited to, Ti, TiN, Ta, TaN, Mo, Ru, W, WN, TiSiN, WSiN, doped polysilicon, or a combination thereof. Each of the plurality of word lines WL may include metal, conductive metal nitride, or a combination thereof. For example, each of the plurality of word lines WL may include, but is not limited to, Ti, TiN, Ta, TaN, Mo, Ru, W, WN, TiSiN, WSiN, or a combination thereof.

Each of both sidewalls of the plurality of back gate electrodes BG in the first horizontal direction (the X direction) may be covered by a back gate dielectric layer 112. The back gate dielectric layer 112 may be located between one back gate electrode BG and one channel layer CHL adjacent thereto. The back gate electrode BG may be spaced apart from the plurality of bit lines BL in the vertical direction (the Z direction) with the back gate dielectric layer 112 therebetween.

A capping insulating pattern 116 may be disposed on the back gate electrode BG. In some embodiments, the capping insulating pattern 116 and the back gate electrode BG may overlap each other in the vertical direction (the Z direction), and the both sidewalls of each of the capping insulating pattern 116 and the back gate electrode BG in the first horizontal direction (the X direction) may be in contact with the back gate dielectric layer 112 and covered by the back gate dielectric layer 112. The back gate electrode BG may be spaced apart from the capacitor structure CTST in the vertical direction (the Z direction) with the capping insulating pattern 116 therebetween. In some embodiments, the capping insulating pattern 116 may include silicon oxide, silicon nitride, or a combination thereof.

According to embodiments, one sidewall of the channel layer CHL in the first horizontal direction (the X direction) may be in contact with the back gate dielectric layer 112, and the other sidewall thereof may be in contact with the gate dielectric layer 122, a first buried insulating pattern 126, and a second buried insulating pattern 127. A portion of the other sidewall of the channel layer CHL may be covered by the gate dielectric layer 122, and the other portion of the other sidewall thereof may be covered by the first buried insulating pattern 126 and the second buried insulating pattern 127. The gate dielectric layer 122 may be located closer to the capacitor structure CTST than the first buried insulating pattern 126 and the second buried insulating pattern 127, and the first buried insulating pattern 126 and the second buried insulating pattern 127 may be located closer to the peripheral circuit structure PRST than the gate dielectric layer 122. One sidewall of the gate dielectric layer 122 in the first horizontal direction (the X direction) may be in contact with the channel layer CHL, and the other sidewall thereof may be in contact with an insulating pattern 128 and the word line WL. A portion of the other sidewall of the gate dielectric layer 122 may be covered by the insulating pattern 128, and the other portion of the other sidewall thereof may be covered by the word line WL. The insulating pattern 128 may be located closer to the capacitor structure CTST than the word line WL, and the word line WL may be located closer to the peripheral circuit structure PRST than the insulating pattern 128. The first buried insulating pattern 126, the second buried insulating pattern 127, the pair of word lines WL, and the pair of insulating patterns 128 may overlap each other in the vertical direction (the Z direction). In some embodiments, the isolation insulating pattern 124, the first buried insulating pattern 126, the second buried insulating pattern 127, and the insulating pattern 128 may each include silicon oxide, silicon nitride, or a combination thereof.

According to embodiments, the back gate dielectric layer 112 and the gate dielectric layer 122 may each include a silicon oxide layer, a high-k dielectric layer, or a combination thereof. As used herein, the term “high-k dielectric layer” represents a dielectric layer having a higher dielectric constant than silicon oxide. In embodiments, the back gate dielectric layer 112 and the gate dielectric layer 122 may each include at least one material selected from a group consisting of silicon oxide, hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), and lead scandium tantalum oxide (PbScTaO). The plurality of back gate electrodes BG, the plurality of word lines WL, the plurality of channel layers CHL, the plurality of back gate dielectric layers 112, and the plurality of gate dielectric layers 122 may constitute the plurality of VCTs CTR.

FIG. 4 shows an example in which the lower surfaces of the plurality of back gate electrodes BG are arranged closer to the plurality of bit lines BL than the lower surfaces of the plurality of word lines WL, but the inventive concept is not limited thereto. For example, the lower surfaces of plurality of back gate electrodes BG may be at the same vertical level as the lower surfaces of plurality of word lines WL, or may be farther away from plurality of bit lines BL than the lower surfaces of plurality of word lines WL.

The capacitor structure CTST may include the plurality of contact plugs 130 and a plurality of capacitors 150 which are disposed above the plurality of channel layers CHL. Each of the plurality of contact plugs 130 may be disposed on a corresponding channel layer CHL among the plurality of channel layers CHL and thus be electrically connected to the corresponding channel layer CHL among the plurality of channel layers CHL.

According to embodiments, the plurality of contact plugs 130 may be spaced apart from the plurality of bit lines BL in the vertical direction (the Z direction) with the plurality of channel layers CHL therebetween. A plurality of contact plugs 130 may be arranged in a matrix pattern and spaced apart from each other in the first horizontal direction (the X direction) and the second horizontal direction (the Y direction). Each of the plurality of contact plugs 130 may be connected to a respective one of the plurality of channel layers CHL in a one-to-one correspondence.

In some embodiments, the plurality of contact plugs 130 may each include metal, conductive metal nitride, metal silicide, doped polysilicon, or a combination thereof. For example, the plurality of contact plugs 130 may each include Ti, TiN, Ta, TaN, Mo, Ru, W, WN, Co, Ni, TiSi, TiSiN, WSi, WSiN, TaSi, TaSiN, RuTiN, CoSi, NiSi, doped polysilicon, or a combination thereof.

In some embodiments, each of the plurality of contact plugs 130 may include a first conductive pattern 134, a second conductive pattern 136, and a third conductive pattern 138, which are stacked in this order above each of the plurality of channel layers CHL. The first conductive pattern 134 may include a semiconductor material, and the second conductive pattern 136 and the third conductive pattern 138 may include a metal-based material. For example, the first conductive pattern 134 may include doped polysilicon, the second conductive pattern 136 may include metal silicide, and the third conductive pattern 138 may include metal. However, embodiments are not limited thereto. In some embodiments, the first conductive pattern 134 may have a multi-layer structure and include, for example, an undoped polysilicon layer and a doped polysilicon layer stacked on the undoped polysilicon layer. The first conductive pattern 134 may be referred to as a buried contact (BC), and the third conductive pattern 138 may be referred to as a landing pad (LP). The second conductive pattern 136 may represent a metal silicide layer that is located between the BC and the LP.

A spacer structure 140 may be located on a sidewall 130S of the contact plug 130 so as to surround the contact plug 130 in the first horizontal direction (the X direction) and the second horizontal direction (the Y direction). The spacer structure 140 may electrically isolate adjacent contact plugs 130 from each other so that each of the plurality of contact plugs 130 may operate electrically independently. The spacer structure 140 may include an outer spacer 142, a middle spacer 144, and an inner spacer 146 that are sequentially arranged on the sidewall 130S of the contact plug 130.

In some embodiments, the outer spacer 142 may extend conformally on the contact plug 130 and may not include a portion that overlaps the inner spacer 146 in the vertical direction (the Z direction). In some embodiments, the outer spacer 142 may include a portion that overlaps the inner spacer 146 in the vertical direction (the Z direction).

In some embodiments, the middle spacer 144 may extend conformally on the outer spacer 142 and onto the capping insulating pattern 116 and may include a portion that overlaps the inner spacer 146 in the vertical direction (the Z direction). In some embodiments, the middle spacer 144 may extend conformally on the contact plug 130 and may not include a portion that overlaps the inner spacer 146 in the vertical direction (the Z direction).

In some embodiments, the inner spacer 146 may be located on the middle spacer 144 and fill any remaining space, not filled by the outer spacer 142 and the middle spacer 144, in the space between a pair of adjacent contact plugs 130.

The contact plug 130 may not be in contact with the inner spacer 146 in the first horizontal direction (the X direction) and the second horizontal direction (the Y direction). For example, the contact plug 130 may be in contact with only the outer spacer 142 in the first horizontal direction (the X direction) and the second horizontal direction (the Y direction). The contact plug 130 may be spaced apart from the inner spacer 146 in the first horizontal direction (the X direction) and the second horizontal direction (the Y direction) with the outer spacer 142 and the middle spacer 144 therebetween. Also, the contact plug 130 may be spaced apart from the middle spacer 144 in the first horizontal direction (the X direction) and the second horizontal direction (the Y direction) with the outer spacer 142 therebetween.

The outer spacer 142, the middle spacer 144, and the inner spacer 146 may overlap the contact plug 130 in the first horizontal direction (the X direction) and the second horizontal direction (the Y direction). The lower surfaces of the lowermost ends of the outer spacer 142, the middle spacer 144, and the inner spacer 146 may be coplanar with the lower surface of the first conductive pattern 134 of the contact plug 130, and the upper surfaces of the uppermost ends of the outer spacer 142, the middle spacer 144, and the inner spacer 146 may be coplanar with the upper surface of the third conductive pattern 138 of the contact plug 130.

The outer spacer 142 may have a cylindrical shape that surrounds the sidewall of the contact plug 130 in the first horizontal direction (the X direction) and the second horizontal direction (the Y direction). The middle spacer 144 may include a first section 144_1 that has a cylindrical shape surrounding the sidewall of the contact plug 130 in the first horizontal direction (the X direction) and the second horizontal direction (the Y direction) and a second section 144_2 that protrudes from the lowermost end of the first section 144_1 and extends in the first horizontal direction (the X direction) and the second horizontal direction (the Y direction). The first section 144_1 may be provided in plurality to surround the sidewalls of the plurality of contact plugs 130 in the first horizontal direction (the X direction) and the second horizontal direction (the Y direction), and the second section 144_2 may be located between a pair of first sections 144_1 spaced apart from each other among the plurality of first sections 144_1 and connect the lowermost end of one of the pair of first sections 144_1 to the lowermost end of the other of the pair of first sections 144_1. For example, each of the plurality of first sections 144_1 of the middle spacer 144 may be located on the sidewall of a corresponding contact plug 130 among the plurality of contact plugs 130, and the second section 144_2 may connect the plurality of first sections 144_1 to each other. The first section 144_1 may include a portion of the middle spacer 144, which is located between the contact plug 130 and the inner spacer 146, and the second section 144_2 may include a portion of the middle spacer 144, which is located between the capping insulating pattern 116 and the inner spacer 146 or between the isolation insulating pattern 124 and the inner spacer 146.

The first section 144_1 covers the sidewall of the outer spacer 142 and extends in the vertical direction (the Z direction). One end of the first section 144_1 may be in contact with the upper surface of the channel structure CHST, and the other end of the first section 144_1 may be in contact with the lower surface of the capacitor 150.

The second section 144_2 may partially cover the upper surface of the channel structure CHST and extend in the first horizontal direction (the X direction) and the second horizontal direction (the Y direction) and may be in contact with the sidewall of the outer spacer 142. For example, the second section 144_2 may cover a portion of the upper surface of the channel structure CHST, which is not covered by the contact plug 130 and the outer spacer 142. For example, the second section 144_2 may cover the upper surfaces of the capping insulating pattern 116 and the isolation insulating pattern 124.

In some embodiments, the outer spacer 142 may include a first sub-spacer 142_1 and a second sub-spacer 142_2. The first sub-spacer 142_1 may cover the sidewall of the first conductive pattern 134, and the second sub-spacer 142_2 may cover the sidewalls of the second conductive pattern 136 and the third conductive pattern 138.

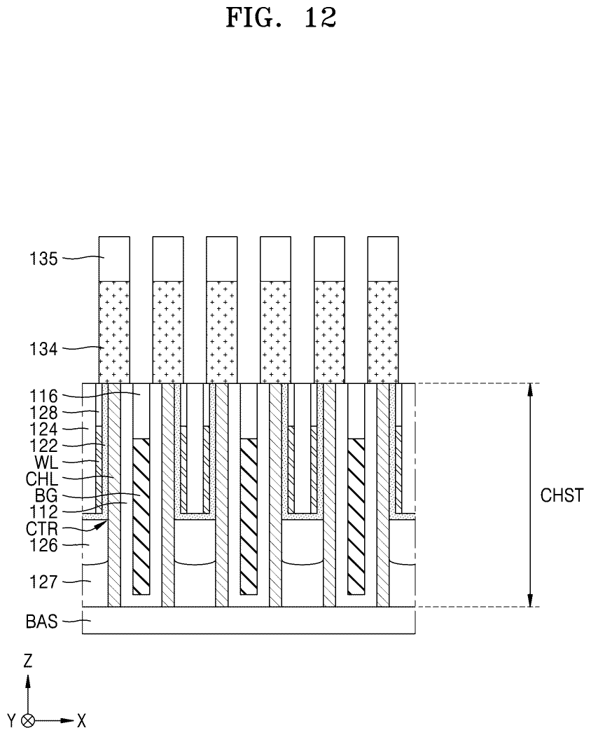

The first sub-spacer 142_1 may contain a different material than the second sub-spacer 142_2. For example, the first sub-spacer 142_1 may include a first element, and the second sub-spacer 142_2 may include the first element and further include a second element different from the first element. For example, the first element may include silicon and nitrogen, and the second element may include oxygen. For example, the first sub-spacer 142_1 may not contain oxygen, and the second sub-spacer 142_2 may contain oxygen. For example, the first sub-spacer 142_1 may contain silicon nitride, and the second sub-spacer 142_2 may contain silicon oxynitride. The first sub-spacer 142_1 may represent a nitride layer made by performing nitridation on the surface of the first conductive pattern 134, and the second sub-spacer 142_2 may represent a nitride layer made by performing nitridation on the surface of a contact plug sacrificial pattern 135 (see FIG. 12) used to form the second conductive pattern 136 and the third conductive pattern 138.

In some embodiments, the middle spacer 144 may contain the same material as the inner spacer 146, but in a different composition ratio. For example, both the middle spacer 144 and the inner spacer 146 may include silicon nitride, and the middle spacer 144 may have a relatively higher nitrogen content compared to the inner spacer 146. For example, the middle spacer 144 may have a lower composition ratio of silicon than the composition ratio of silicon in the inner spacer 146 and may have a higher composition ratio of nitrogen than the composition ratio of nitrogen in the inner spacer 146. In some embodiments, the middle spacer 144 may contain a different material than the inner spacer 146. For example, the middle spacer 144 may include any one of silicon carbonitride, silicon oxynitride, silicon oxycarbonitride, and silicon nitride.

In some embodiments, the inner spacer 146 may include silicon nitride. For example, the middle spacer 144 and the inner spacer 146 may include silicon nitride, and the inner spacer 146 may have a relatively lower nitrogen content compared to the middle spacer 144. The inner spacer 146 may have a higher composition ratio of silicon than the composition ratio of silicon in the middle spacer 144 and have a lower composition ratio of nitrogen than the composition ratio of nitrogen in the middle spacer 144.

The capacitor 150 may include a plurality of lower electrodes 152 respectively connected to the plurality of contact plugs 130, a capacitor dielectric layer 154 conformally covering a surface of each of the plurality of lower electrodes 152, and an upper electrode 156 covering the plurality of lower electrodes 152 with the capacitor dielectric layer 154 therebetween. Each of the plurality of lower electrodes 152 may be connected to the channel layer CHL via one contact plug 130 selected from among the plurality of contact plugs 130. The third conductive pattern 138 in each of the plurality of contact plugs 130 may function as an LP that is in contact with one lower electrode 152 selected from among the plurality of lower electrodes 152.

Each of the plurality of lower electrodes 152 may have a solid columnar or pillar-like structure with a circular horizontal cross-section, but embodiments are not limited thereto. In some embodiments, each of the plurality of lower electrodes 152 may have a cylindrical shape that is closed at the bottom. In some embodiments, the plurality of lower electrodes 152 may be arranged in a line in each of the first horizontal direction (the X direction) and the second horizontal direction (the Y direction) to form a matrix shape. In some embodiments, the plurality of lower electrodes 152 may be arranged in a zigzag pattern in the first horizontal direction (the X direction) or the second horizontal direction (the Y direction) to form a honeycomb shape. The plurality of lower electrodes 152 may include, for example, impurity-doped silicon, metal such as tungsten and copper, or a conductive metal compound such as titanium nitride.

The capacitor dielectric layer 154 may conformally cover the surfaces of the plurality of lower electrodes 152. In some embodiments, the capacitor dielectric layer 154 may include a high-k dielectric layer. In some embodiments, the capacitor dielectric layer 154 may include metal oxide including at least one metal selected from a group consisting of hafnium (Hf), zirconium (Zr), aluminum (Al), niobium (Nb), cerium (Ce), lanthanum (La), tantalum (Ta), and titanium (Ti).

In some embodiments, each of the plurality of lower electrodes 152 and the upper electrode 156 may include Nb, Nb oxide, Nb nitride, Nb oxynitride, Ti, Ti oxide, Ti nitride, Ti oxynitride, Co, Co oxide, Co nitride, Co oxynitride, Sn, Sn oxide, Sn nitride, Sn oxynitride, or a combination thereof. In some embodiments, each of the plurality of lower electrodes 152 and the upper electrode 156 may include TaN, TiAlN, TaAlN, V, VN, Mo, MoN, W, WN, Ru, RuO₂, SrRuO₃, Ir, IrO₂, Pt, PtO, SRO(SrRuO₃), BSRO((Ba, Sr)RuO₃), CRO(CaRuO₃), LSCO((La, Sr)CoO₃), or a combination thereof. However, the materials for constituting each of the plurality of lower electrodes 152 and the upper electrode 156 are not limited to the examples described above. In some embodiments, the upper electrode 156 may further include at least one of a doped semiconductor material layer and a main electrode layer in addition to the metal material and may have a stack structure thereof. The doped semiconductor material layer may include, for example, at least one of doped polysilicon and doped polycrystalline silicon germanium (poly-SiGe). The main electrode layer may include a metal material. The main electrode layer may include, for example, at least one of metal oxide, metal nitride, metal carbide, and metal silicide.

In some embodiments, a first bonding insulating layer 166 may be disposed on the bit line insulating layer OBL of the bit line structure BLST. For example, the first bonding insulating layer 166 may cover the lower surface of the bit line insulating layer OBL. For example, the first bonding insulating layer 166 may include silicon oxide or silicon carbonitride (SiCN). A second bonding insulating layer 266 may be disposed on the peripheral circuit structure PRST. For example, the second bonding insulating layer 266 may cover the upper surfaces of an inter-wiring insulating layer 220 and a wiring structure 230. The second bonding insulating layer 266 may include silicon oxide or silicon carbonitride (SiCN). The first bonding insulating layer 166 and the second bonding insulating layer 266 may be bonded to each other while forming a covalent bond. The memory cell array structure MCA and the peripheral circuit structure PRST may be bonded to each other by the first bonding insulating layer 166 and the second bonding insulating layer 266, and thus, the memory cell array structure MCA may be stacked on the peripheral circuit structure PRST.

The peripheral circuit structure PRST may include a peripheral circuit substrate 202 having a plurality of active regions AC defined by a circuit device isolation layer 204, a plurality of circuit gate structures 210 disposed on the plurality of active regions AC of the peripheral circuit substrate 202, an inter-wiring insulating layer 220 provided on the peripheral circuit substrate 202 and covering the plurality of circuit gate structures 210, and the wiring structure 230 surrounded by the inter-wiring insulating layer 220 and electrically connected to the plurality of active regions AC and/or the plurality of circuit gate structures 210. The plurality of circuit gate structures 210 disposed on the plurality of active regions AC may constitute the plurality of peripheral circuit transistors PTR.

The peripheral circuit substrate 202 may include, for example, semiconductor materials, such as a group IV semiconductor material, a group III-V semiconductor material, a group II-VI semiconductor material, and a group II-VI oxide semiconductor material. The group IV semiconductor material may include, for example, silicon (Si), germanium (Ge), or silicon-germanium (Si—Ge). The group III-V semiconductor material may include, for example, gallium arsenide (GaAs), indium phosphide (InP), gallium phosphide (GaP), indium arsenide (InAs), indium antimonide (InSb), or indium gallium arsenide (InGaAs). The group II-VI semiconductor material may include, for example, zinc telluride (ZnTe) or cadmium sulfide (CdS). The peripheral circuit substrate 202 may include a bulk wafer or an epitaxial layer. The peripheral circuit substrate 202 may be provided as a bulk wafer or an epitaxial layer. In embodiments, the peripheral circuit substrate 202 may include a silicon-on-insulator (SOI) substrate or a germanium-on-insulator (GeOI) substrate. The peripheral circuit substrate 202 may have an active region AC defined by the circuit device isolation layer 204, and the active region AC and the circuit gate structure 210 may constitute a peripheral circuit transistor PTR.

The circuit gate structure 210 may include a circuit gate electrode 214 above the active region AC, a circuit gate insulating layer 212 between the active region AC and the circuit gate electrode 214, a circuit gate capping layer 216 covering the circuit gate electrode 214, and a circuit gate spacer 218 covering the side surfaces of the circuit gate insulating layer 212, the circuit gate electrode 214, and the circuit gate capping layer 216.

The wiring structure 230 may include a circuit wiring line and a circuit wiring contact. The wiring structure 230 may include conductive materials, such as copper (Cu), aluminum (Al), tungsten (W), silver (Ag), gold (Au), and a combination thereof. The inter-wiring insulating layer 220 may include an insulating material containing silicon oxide, silicon nitride, a low-k material, or a combination thereof. The low-k material may represent a material having a lower dielectric constant than silicon oxide and include, for example, phosphosilicate glass (PSG), borophosphosilicate glass (BPSG), fluorosilicate glass (FSG), organosilicate glass (OSG), spin-on-glass (SOG), spin-on-polymer, or a combination thereof. In some embodiments, the inter-wiring insulating layer 220 may include an ultra low-k (ULK) layer having an ultra low dielectric constant K of about 2.2 to about 2.4. The ULK layer may include SiOC or SiCOH.

The semiconductor device 100 according to embodiments includes the contact plug 130 electrically connecting the channel layer CHL to the capacitor 150 and also includes the spacer structure 140 provided on the sidewall 130S of the contact plug 130 to surround the contact plug 130. The spacer structure 140 includes the outer spacer 142, the middle spacer 144, and the inner spacer 146 having different etch selectivities, which may minimize the consumption of the spacer structure 140 between the plurality of contact plugs 130 during a process of forming the plurality of contact plugs 130. Ultimately, the occurrence of bridges between the plurality of contact plugs 130 may be minimized to provide the semiconductor device having improved operational reliability.

Specifically, during the formation of the plurality of contact plugs 130, in a structure in which a contact plug sacrificial layer 135 (see FIG. 12) is stacked on the first conductive pattern 134, a process of etching the contact plug sacrificial pattern 135 may be performed on the structure described above to remove the contact plug sacrificial pattern 135, thereby forming the second conductive pattern 136 and the third conductive pattern 138 in a space from which the contact plug sacrificial pattern 135 has been removed. The spacer structure 140 according to the inventive concept includes the outer spacer 142, the middle spacer 144, and the inner spacer 146, which may minimize the consumption of the spacer structure 140 during the etching process of the contact plug sacrificial pattern 135. Ultimately, the occurrence of bridges between the plurality of contact plugs 130 may be minimized to provide the semiconductor device having the improved operational reliability.

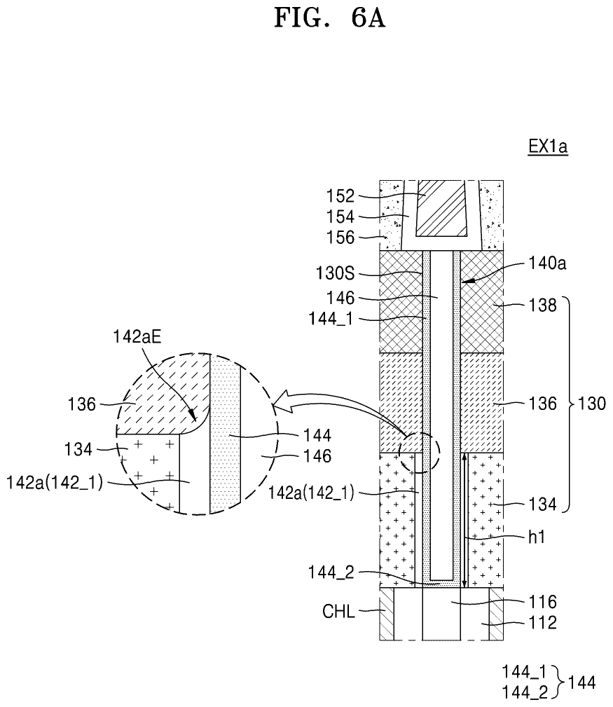

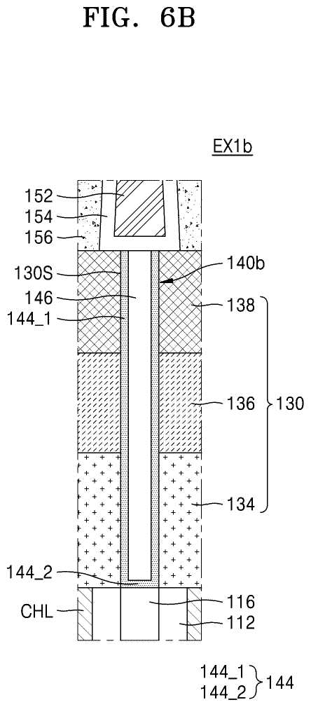

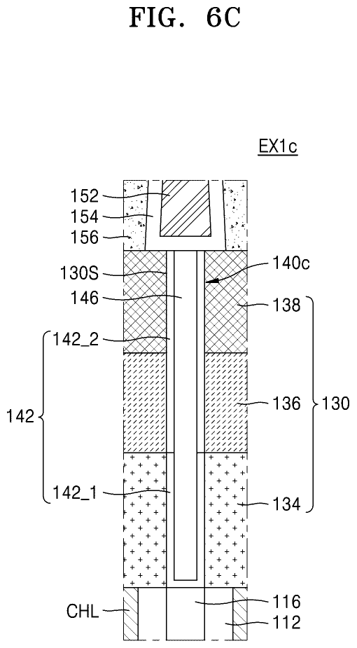

FIGS. 6A to 6C are diagrams showing semiconductor devices according to some embodiments.

FIGS. 6A to 6C are diagrams showing the semiconductor devices, in a region corresponding to region “EX1” of FIG. 4. Since semiconductor devices EX1a, EX1b, and EX1c described with reference to FIGS. 6A to 6C, respectively, are configured in a substantially similar manner to the semiconductor device 100 described above with reference to FIGS. 3 to 5, the description below focuses on the differences therebetween.

Referring to FIG. 6A, a spacer structure 140 may be located on a sidewall 130S of the contact plug 130 so as to surround the contact plug 130 in the first horizontal direction (the X direction) and the second horizontal direction (the Y direction). The spacer structure 140 may electrically isolate adjacent contact plugs 130 from each other so that each of the plurality of contact plugs 130 may operate electrically independently. The spacer structure 140 may include an outer spacer 142a, a middle spacer 144, and an inner spacer 146 that are sequentially arranged on the sidewall 130S of the contact plug 130.

In some embodiments, the outer spacer 142a may extend conformally on the contact plug 130 and may not include a portion that overlaps the inner spacer 146 in the vertical direction (the Z direction).

In some embodiments, the outer spacer 142a may partially cover the sidewall 130S of the contact plug 130. In embodiments, the outer spacer 142a may completely cover the sidewall of the first conductive pattern 134 and may not completely cover the sidewalls of the second conductive pattern 136 and the third conductive pattern 138. For example, the outer spacer 142a may include a first sub-spacer 142_1. The first conductive pattern 134 may be spaced apart from the middle spacer 144 with the outer spacer 142a (the first sub-spacer 142_1) therebetween, and the second conductive pattern 136 and the third conductive pattern 138 may be in contact with the middle spacer 144. FIG. 6A illustrates embodiments in which the outer spacer 142a completely covers the sidewall of the first conductive pattern 134 and does not completely cover the sidewalls of the second conductive pattern 136 and the third conductive pattern 138, but the inventive concept is not limited to embodiments described with reference to FIG. 6A.

In embodiments, the outer spacer 142a may cover a lower portion of the sidewall of the first conductive pattern 134, may not cover an upper portion of the sidewall of the first conductive pattern 134, and may not cover all of the sidewalls of the second conductive pattern 136 and the third conductive pattern 138. For example, the outer spacer 142a may include the first sub-spacer 142_1. The lower portion of the first conductive pattern 134 may be spaced apart from the middle spacer 144 with the outer spacer 142a (the first sub-spacer 142_1) therebetween, the upper portion of the first conductive pattern 134 may be in contact with the middle spacer 144, and the second conductive pattern 136 and the third conductive pattern 138 may be in contact with the middle spacer 144.

In embodiments, the outer spacer 142a may completely cover the sidewall of the first conductive pattern 134, cover lower portions of the sidewalls of the second conductive pattern 136 and the third conductive pattern 138, and not cover upper portions of the sidewalls of the second conductive pattern 136 and the third conductive pattern 138. For example, the outer spacer 142 may include a first sub-spacer 142_1 and a second sub-spacer 142_2. The first conductive pattern 134 may be spaced apart from the middle spacer 144 with the first sub-spacer 142_1 therebetween, the lower portions of the second conductive pattern 136 and the third conductive pattern 138 may be spaced apart from the middle spacer 144 with the second sub-spacer 142_2 therebetween, and the upper portions of the second conductive pattern 136 and the third conductive pattern 138 may be in contact with the middle spacer 144. The materials for constituting the first sub-spacer 142_1 and the second sub-spacer 142_2 may be similar to those described above with reference to FIGS. 3 to 5.

The upper surface of an upper end 142aE of the outer spacer 142a may have a concave shape. The concave upper surface of the upper end 142aE of the outer spacer 142a may be due to a portion of the outer spacer 142a being consumed together during a wet etching process to form the contact plug 130. The vertical length of a portion of the outer spacer 142a, adjacent to the sidewall 130S of the contact plug 130, may be different from the vertical length of a portion of the outer spacer 142a, distant from the sidewall 130S of the contact plug 130. A vertical length h1 of the outer spacer 142a may increase or decrease according to the distance from the sidewall 130S of the contact plug 130 in the first horizontal direction (the X direction) and the second horizontal direction (the Y direction). For example, the vertical length h1 of the outer spacer 142a may decrease towards the sidewall 130S of the contact plug 130.

The middle spacer 144 may include a first section 144_1 that has a cylindrical shape surrounding the sidewall of the contact plug 130 in the first horizontal direction (the X direction) and the second horizontal direction (the Y direction) and a second section 144_2 that protrudes from the lowermost end of the first section 144_1 and extends in the first horizontal direction (the X direction) and the second horizontal direction (the Y direction).

The first section 144_1 covers the sidewalls of the contact plug 130 and the outer spacer 142a and extends in the vertical direction (the Z direction). One end of the first section 144_1 may be in contact with the upper surface of the channel structure CHST, and the other end of the first section 144_1 may be in contact with the lower surface of the capacitor 150.

The second section 144_2 may partially cover the upper surface of the channel structure CHST and extend in the first horizontal direction (the X direction) and the second horizontal direction (the Y direction) and may be in contact with the sidewall of the outer spacer 142a. For example, the second section 144_2 may cover a portion of the upper surface of the channel structure CHST, which is not covered by the contact plug 130 and the outer spacer 142a. For example, the second section 144_2 may cover the upper surfaces of the capping insulating pattern 116 and the isolation insulating pattern 124.

Referring to FIG. 6B, a spacer structure 140 may be located on a sidewall 130S of the contact plug 130 so as to surround the contact plug 130 in the first horizontal direction (the X direction) and the second horizontal direction (the Y direction). The spacer structure 140 may electrically isolate adjacent contact plugs 130 from each other so that each of the plurality of contact plugs 130 may operate electrically independently. The spacer structure 140 may include a middle spacer 144 and an inner spacer 146 that are sequentially arranged on the sidewall 130S of the contact plug 130.

In some embodiments, the middle spacer 144 may extend conformally on the isolation insulating pattern 124 and onto the capping insulating pattern 116 and may include a portion that overlaps the inner spacer 146 in the vertical direction (the Z direction). In some embodiments, the middle spacer 144 may extend conformally on the contact plug 130 and may not include a portion that overlaps the inner spacer 146 in the vertical direction (the Z direction).

The contact plug 130 may not be in contact with the inner spacer 146 in the first horizontal direction (the X direction) and the second horizontal direction (the Y direction). For example, the contact plug 130 may be in contact with only the middle spacer 144 in the first horizontal direction (the X direction) and the second horizontal direction (the Y direction). The contact plug 130 may be spaced apart from the inner spacer 146 in the first horizontal direction (the X direction) and the second horizontal direction (the Y direction) with the middle spacer 144 therebetween.

The middle spacer 144 and the inner spacer 146 may overlap the contact plug 130 in the first horizontal direction (the X direction) and the second horizontal direction (the Y direction). The lower surfaces of the lowermost ends of the middle spacer 144 and the inner spacer 146 may be coplanar with the lower surface of the first conductive pattern 134 of the contact plug 130, and the upper surfaces of the uppermost ends of the middle spacer 144 and the inner spacer 146 may be coplanar with the upper surface of the third conductive pattern 138 of the contact plug 130.

The middle spacer 144 may include a first section 144_1 that has a cylindrical shape surrounding the sidewall of the contact plug 130 in the first horizontal direction (the X direction) and the second horizontal direction (the Y direction) and a second section 144_2 that protrudes from the lowermost end of the first section 144_1 and extends in the first horizontal direction (the X direction) and the second horizontal direction (the Y direction).

The first section 144_1 covers the sidewall of the contact plug 130 and extends in the vertical direction (the Z direction). One end of the first section 144_1 may be in contact with the upper surface of the channel structure CHST, and the other end of the first section 144_1 may be in contact with the lower surface of the capacitor 150.

The second section 144_2 may partially cover the upper surface of the channel structure CHST and extend in the first horizontal direction (the X direction) and the second horizontal direction (the Y direction) and may be in contact with the sidewall of the contact plug 130. For example, the second section 144_2 may cover a portion of the upper surface of the channel structure CHST, which is not covered by the contact plug 130. For example, the second section 144_2 may cover the upper surfaces of the capping insulating pattern 116 and the isolation insulating pattern 124.

Referring to FIG. 6C, a spacer structure 140 may be located on a sidewall 130S of the contact plug 130 so as to surround the contact plug 130 in the first horizontal direction (the X direction) and the second horizontal direction (the Y direction). The spacer structure 140 may electrically isolate adjacent contact plugs 130 from each other so that each of the plurality of contact plugs 130 may operate electrically independently. The spacer structure 140 may include an outer spacer 142 and an inner spacer 146 that are sequentially arranged on the sidewall 130S of the contact plug 130.

In some embodiments, the outer spacer 142 may extend conformally on the contact plug 130 and may include a portion that overlaps the inner spacer 146 in the vertical direction (the Z direction).

In some embodiments, the inner spacer 146 may be located on the outer spacer 142 and fill any remaining space, not filled by the outer spacer 142, in the space between a pair of adjacent contact plugs 130.

The contact plug 130 may not be in contact with the inner spacer 146 in the first horizontal direction (the X direction) and the second horizontal direction (the Y direction). For example, the contact plug 130 may be in contact with only the outer spacer 142 in the first horizontal direction (the X direction) and the second horizontal direction (the Y direction). The contact plug 130 may be spaced apart from the inner spacer 146 in the first horizontal direction (the X direction) and the second horizontal direction (the Y direction) with the outer spacer 142 therebetween.

The outer spacer 142 and the inner spacer 146 may overlap the contact plug 130 in the first horizontal direction (the X direction) and the second horizontal direction (the Y direction). The lower surfaces of the lowermost ends of the outer spacer 142 and the inner spacer 146 may be coplanar with the lower surface of the first conductive pattern 134 of the contact plug 130, and the upper surfaces of the uppermost ends of the outer spacer 142 and the inner spacer 146 may be coplanar with the upper surface of the third conductive pattern 138 of the contact plug 130.

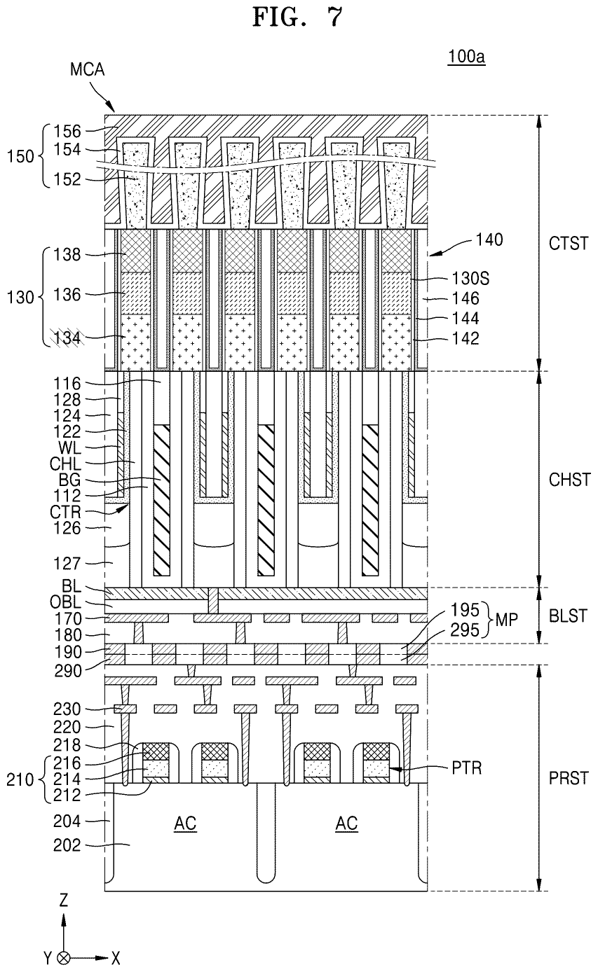

FIG. 7 is a diagram showing a semiconductor device 100a according to embodiments.

FIG. 7 is a diagram of the semiconductor device 100a, in an area corresponding to a cross-section taken along line IIA-IIA′ of FIG. 3.

Referring to FIG. 7, the semiconductor device 100a may include a peripheral circuit structure PRST and a memory cell array structure MCA stacked on the peripheral circuit structure PRST and having a plurality of memory cells arranged therein. In the semiconductor device 100a, the memory cell array structure MCA may include a bit line structure BLST, a channel structure CHST, and a capacitor structure CTST, which are sequentially stacked above the peripheral circuit structure PRST. In some embodiments, the semiconductor device 100a may have a CoP structure in which the memory cell array structure MCA and the peripheral circuit structure PRST overlap each other in the vertical direction (the Z direction).

The peripheral circuit structure PRST, the bit line structure BLST, the channel structure CHST, and the capacitor structure CTST of FIG. 7 are substantially the same as the peripheral circuit structure PRST, the bit line structure BLST, the channel structure CHST, and the capacitor structure CTST of FIG. 4, and thus, repeated descriptions thereof may be omitted.

The bit line structure BLST may further include a cell wiring structure 170 disposed below the bit line insulating layer OBL and a cell inter-wiring insulating layer 180 surrounding the cell wiring structure 170. The cell wiring structure 170 may include a plurality of cell wiring lines and a plurality of cell wiring contacts. The cell wiring structure 170 may include conductive materials, such as copper (Cu), aluminum (Al), tungsten (W), silver (Ag), gold (Au), and a combination thereof. The cell inter-wiring insulating layer 180 may include an insulating material containing silicon oxide, silicon nitride, a low-k material, or a combination thereof. In some embodiments, at least one of the plurality of cell wiring contacts of the cell wiring structure 170 may pass through the bit line insulating layer OBL and electrically connect the plurality of bit lines BL to the plurality of cell wiring lines.

Below the cell wiring structure 170 and the cell inter-wiring insulating layer 180, there may be disposed a plurality of upper metal pads 195 electrically connected to the cell wiring structure 170 and a first bonding insulating layer 190 surrounding the plurality of upper metal pads 195. Above the inter-wiring insulating layer 220 and the wiring structure 230, there may be a plurality of lower metal pads 295 electrically connected to the wiring structure 230 and a second bonding insulating layer 290 surrounding the plurality of lower metal pads 295. Each of the first bonding insulating layer 190 and the second bonding insulating layer 290 may include silicon oxide or silicon carbonitride (SiCN). In some embodiments, the peripheral circuit structure PRST and the memory cell array structure MCA may be bonded to each other with a metal-oxide hybrid bonding method. The first bonding insulating layer 190 and the second bonding insulating layer 290 may be in contact with and covalently bonded to each other. The plurality of upper metal pads 195 and the plurality of lower metal pads 295 corresponding to each other may be thermally expanded and brought into contact with each other to form a plurality of bonding pads MP that are diffusion-bonded and integrated together via diffusion of the metal atoms therein.

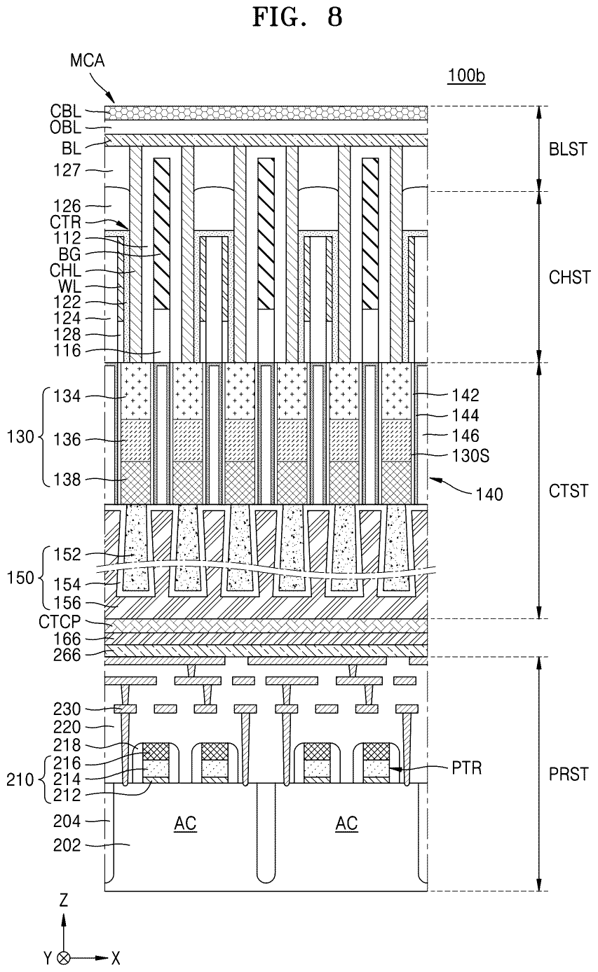

FIG. 8 is a diagram showing a semiconductor device 100b according to embodiments.

FIG. 8 is a diagram of the semiconductor device 100b, in an area corresponding to a cross-section taken along line IIA-IIA′ of FIG. 3.

Referring to FIG. 8, the semiconductor device 100b may include a peripheral circuit structure PRST and a memory cell array structure MCA stacked on the peripheral circuit structure PRST and having a plurality of memory cells arranged therein. In the semiconductor device 100b, the memory cell array structure MCA may include a capacitor structure CTST, a channel structure CHST, and a bit line structure BLST, which are sequentially stacked above the peripheral circuit structure PRST. The capacitor structure CTST, the channel structure CHST, and the bit line structure BLST of FIG. 8 are substantially the same as the capacitor structure CTST, the channel structure CHST, and the bit line structure BLST of FIG. 4, but with the structures inverted upside down, and thus, other repeated descriptions thereof may be omitted.

The capacitor structure CTST includes a plurality of contact plugs 130, a spacer structure 140 surrounding a plurality of contact plugs 130, and a plurality of capacitors 150 including a plurality of lower electrodes 152 connected to the bottom of the plurality of contact plugs 130, a capacitor dielectric layer 154 conformally covering a surface of each of the plurality of lower electrodes 152, and an upper electrode 156 covering the bottom of the plurality of lower electrodes 152 with the capacitor dielectric layer 154 therebetween. In some embodiments, the capacitor structure CTST may further include a capacitor capping layer CTCP covering the lower surface of the upper electrode 156. The capacitor capping layer CTCP may include silicon oxide, silicon nitride, or a combination thereof.

The bit line structure BLST may include a plurality of bit lines BL, and a bit line insulating layer OBL covering the upper surfaces of the plurality of bit lines BL. In some embodiments, the bit line structure BLST may further include a bit line capping layer CBL covering the upper surface of the bit line insulating layer OBL. The bit line capping layer CBL may include silicon nitride.

In some embodiments, the first bonding insulating layer 166 may be disposed on the capacitor capping layer CTCP. For example, the first bonding insulating layer 166 may cover the lower surface of the capacitor capping layer CTCP. The second bonding insulating layer 266 may cover the inter-wiring insulating layer 220 and the wiring structure 230. The second bonding insulating layer 266 and the first bonding insulating layer 166 may be bonded to each other while forming a covalent bond. The memory cell array structure MCA and the peripheral circuit structure PRST may be bonded to each other by the first bonding insulating layer 166 and the second bonding insulating layer 266, and thus, the memory cell array structure MCA may be stacked on the peripheral circuit structure PRST.

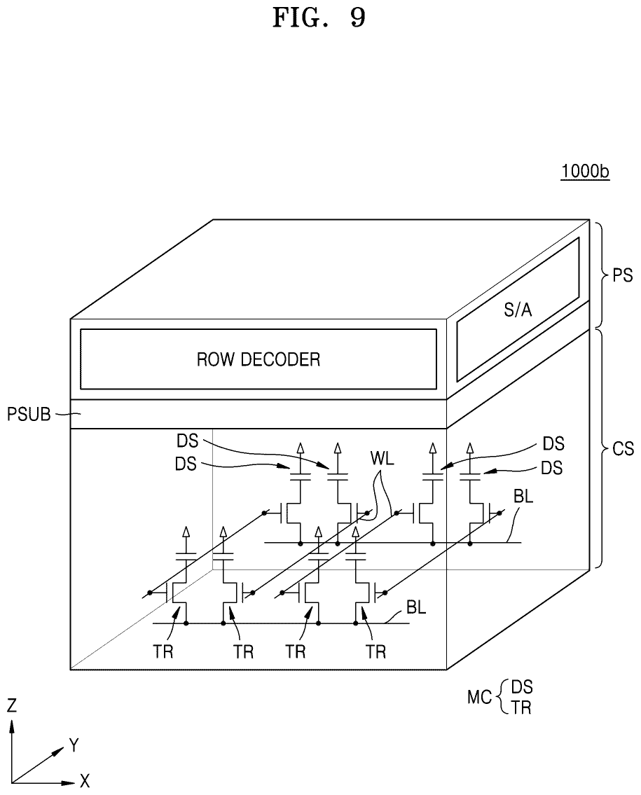

FIG. 9 is a schematic perspective view illustrating a semiconductor device 1000b according to embodiments.

Referring to FIG. 9, the semiconductor device 1000b may include a cell array structure CS and a peripheral circuit structure PS on the cell array structure CS. The peripheral circuit substrate PSUB, the peripheral circuit structure PS, and the cell array structure CS of FIG. 9 are substantially the same as the peripheral circuit substrate PSUB, the peripheral circuit structure PS, and the cell array structure CS of FIG. 2, and thus, repeated descriptions thereof may be omitted.

The peripheral circuit structure PS may be bonded to the cell array structure CS. FIG. 9 shows that the peripheral circuit substrate PSUB is located in the peripheral circuit structure PS on the side facing the cell array structure CS in the vertical direction (the Z direction), but this is only an example. Embodiments are not limited thereto. In some embodiments, the peripheral circuit substrate PSUB may be located in the peripheral circuit structure PS on the side opposite the cell array structure CS in the vertical direction (the Z direction).

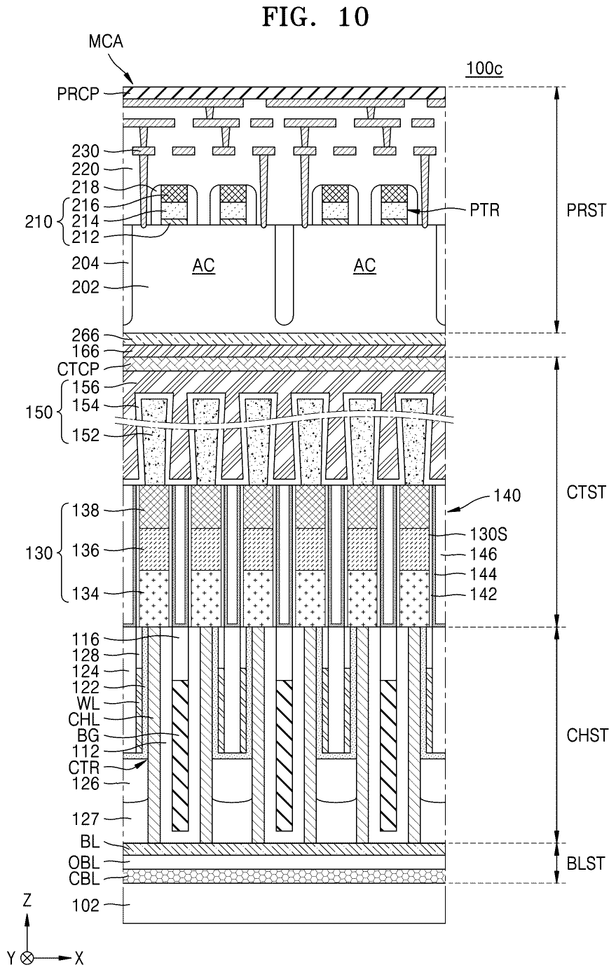

FIG. 10 is a diagram showing a semiconductor device 100c according to embodiments.

Referring to FIG. 10, the semiconductor device 100c may include a memory cell array structure MCA, in which a plurality of memory cells are arranged, and a peripheral circuit structure PRST, which is stacked on the memory cell array structure MCA. The semiconductor device 100c may have a periphery on cell (PoC) structure in which the peripheral circuit structure PRST and the memory cell array structure MCA overlap each other in the vertical direction (the Z direction). In the semiconductor device 100c, the memory cell array structure MCA may include a capacitor structure CTST, a channel structure CHST, and a bit line structure BLST, which are sequentially arranged above the peripheral circuit structure PRST. The peripheral circuit structure PRST, the bit line structure BLST, the channel structure CHST, and the capacitor structure CTST of FIG. 10 are substantially the same as the peripheral circuit structure PRST, the bit line structure BLST, the channel structure CHST, and the capacitor structure CTST of FIG. 4, and thus, repeated descriptions thereof may be omitted.

The capacitor structure CTST may further include a capacitor capping layer CTCP covering the upper surface of the upper electrode 156. The peripheral circuit structure PRST may further include a peripheral circuit capping layer PRCP covering the inter-wiring insulating layer 220 and the wiring structure 230. Each of the capacitor capping layer CTCP and the peripheral circuit capping layer PRCP may include silicon oxide, silicon nitride, or a combination thereof.

In some embodiments, the first bonding insulating layer 166 may be disposed on the capacitor capping layer CTCP. For example, the first bonding insulating layer 166 may cover the upper surface of the capacitor capping layer CTCP. The second bonding insulating layer 266 may cover the lower surface of the peripheral circuit structure PRST. In some embodiments, the second bonding insulating layer 266 may cover the lower surface of the peripheral circuit substrate 202. The second bonding insulating layer 266 and the first bonding insulating layer 166 may be bonded to each other while forming a covalent bond. The memory cell array structure MCA and the peripheral circuit structure PRST may be bonded to each other by the first bonding insulating layer 166 and the second bonding insulating layer 266, and thus, the peripheral circuit structure PRST may be stacked on the memory cell array structure MCA.

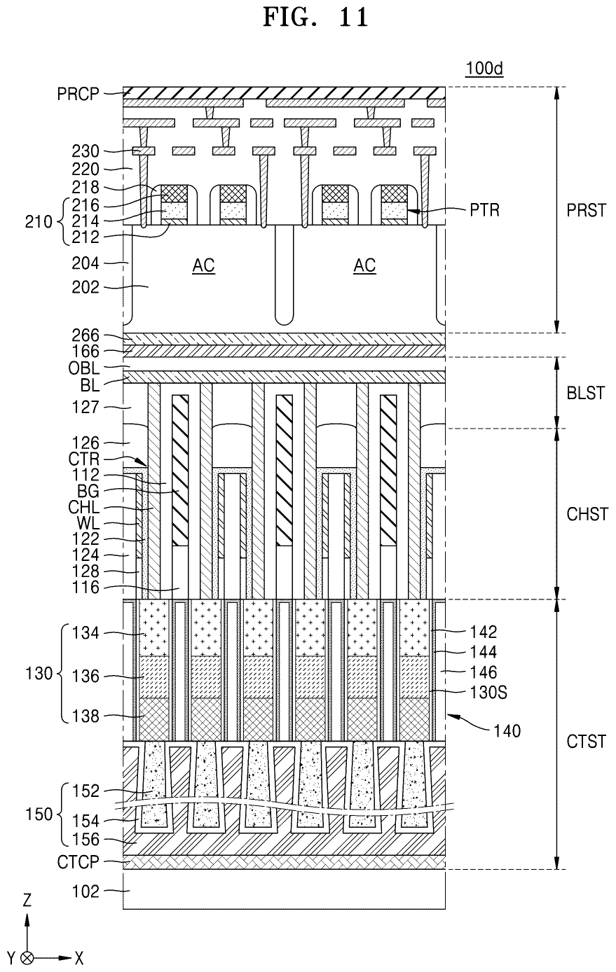

FIG. 11 is a diagram showing a semiconductor device 100d according to embodiments.

Referring to FIG. 11, the semiconductor device 100d may include a memory cell array structure MCA, in which a plurality of memory cells are arranged, and a peripheral circuit structure PRST, which is stacked on the memory cell array structure MCA. The semiconductor device 100d may have a PoC structure in which the peripheral circuit structure PRST and the memory cell array structure MCA overlap each other in the vertical direction (the Z direction). In the semiconductor device 100d, the memory cell array structure MCA may include a bit line structure BLST, a channel structure CHST, and a capacitor structure CTST, which are sequentially arranged above the peripheral circuit structure PRST. The peripheral circuit structure PRST, the bit line structure BLST, the channel structure CHST, and the capacitor structure CTST of FIG. 11 are substantially the same as the peripheral circuit structure PRST, the bit line structure BLST, the channel structure CHST, and the capacitor structure CTST of FIG. 4, and thus, repeated descriptions thereof may be omitted.

The capacitor structure CTST may be attached to a support substrate 102. The support substrate 102 may include, for example, semiconductor materials, such as a group IV semiconductor material, a group III-V semiconductor material, a group II-VI semiconductor material, and a group II-VI oxide semiconductor material. The capacitor structure CTST may further include a capacitor capping layer CTCP covering the lower surface of the upper electrode 156. In some embodiments, the capacitor capping layer CTCP may function as a bonding insulating layer for bonding the support substrate 102 to the capacitor structure CTST. For example, after forming the capacitor structure CTST, the capacitor structure CTST may be attached onto the support substrate 102 such that the capacitor capping layer CTCP of the capacitor structure CTST faces the support substrate 102. For example, the capacitor capping layer CTCP may include silicon oxide, silicon nitride, or a combination thereof.

The peripheral circuit structure PRST may further include a peripheral circuit capping layer PRCP covering the inter-wiring insulating layer 220 and the wiring structure 230. Each of the capacitor capping layer CTCP and the peripheral circuit capping layer PRCP may include silicon oxide, silicon nitride, or a combination thereof.

In some embodiments, the first bonding insulating layer 166 may be disposed on the bit line insulating layer OBL. For example, the first bonding insulating layer 166 may cover the upper surface of the bit line insulating layer OBL. The second bonding insulating layer 266 may cover the lower surface of the peripheral circuit structure PRST. In some embodiments, the second bonding insulating layer 266 may cover the lower surface of the peripheral circuit substrate 202. The second bonding insulating layer 266 and the first bonding insulating layer 166 may be bonded to each other while forming a covalent bond. The memory cell array structure MCA and the peripheral circuit structure PRST may be bonded to each other by the first bonding insulating layer 166 and the second bonding insulating layer 266, and thus, the peripheral circuit structure PRST may be stacked on the memory cell array structure MCA.

FIGS. 12 to 20 are diagrams illustrating a process of manufacturing a semiconductor device, according to embodiments.

Specifically, FIGS. 12 to 20 are diagrams illustrating the manufacturing process of the semiconductor device 100 described with reference to FIGS. 3 to 5, and the semiconductor devices 100a, 100b, 100c, 100d may also be manufactured by a process similar to the manufacturing process described with reference to FIGS. 12 to 20.

Referring to FIG. 12, the channel structure CHST may be provided on a base substrate BAS, and the first conductive pattern 134 and the contact plug sacrificial pattern 135 may be sequentially formed on the channel structure CHST. Various processes generally known to those skilled in the art may be utilized to form the channel structure CHST on the base substrate BAS, and thus, a detailed description of the process of forming the channel structure CHST is omitted.

In order to form the first conductive pattern 134 and the contact plug sacrificial pattern 135, a preliminary first conductive layer and a preliminary contact plug sacrificial layer are sequentially formed on the upper surface of the channel structure CHST. Subsequently, the preliminary first conductive layer and the preliminary contact plug sacrificial layer may be patterned to form the first conductive pattern 134 and the contact plug sacrificial pattern 135.

In some embodiments, the preliminary first conductive layer and the first conductive pattern 134 formed by patterning the preliminary first conductive layer may have a single-layer structure and include a doped polysilicon layer. In some embodiments, the preliminary first conductive layer and the first conductive pattern 134 formed by patterning the preliminary first conductive layer may have a multilayer structure and include, for example, an undoped polysilicon layer and a doped polysilicon layer. The preliminary contact plug sacrificial layer and the contact plug sacrificial pattern 135 formed by patterning the preliminary contact plug sacrificial layer may include plasma enhanced oxide (PEOX), tetraethyl orthosilicate (TEOS), boro tetraethyl orthoSilicate (BTEOS), phosphorous tetraethyl orthosilicate (PTEOS), boro phospho tetraethyl orthosilicate (BPTEOS), boro silicate glass (BSG), phospho silicate glass (PSG), boro phospho silicate glass (BPSG), etc.

A plurality of first conductive patterns 134 and a plurality of contact plug sacrificial patterns 135 may be formed by the patterning the preliminary first conductive layer and the preliminary contact plug sacrificial layer, and the plurality of first conductive patterns 134 and the plurality of contact plug sacrificial patterns 135 may be spaced apart from each other in the first horizontal direction (the X direction) and the second horizontal direction (the y direction).

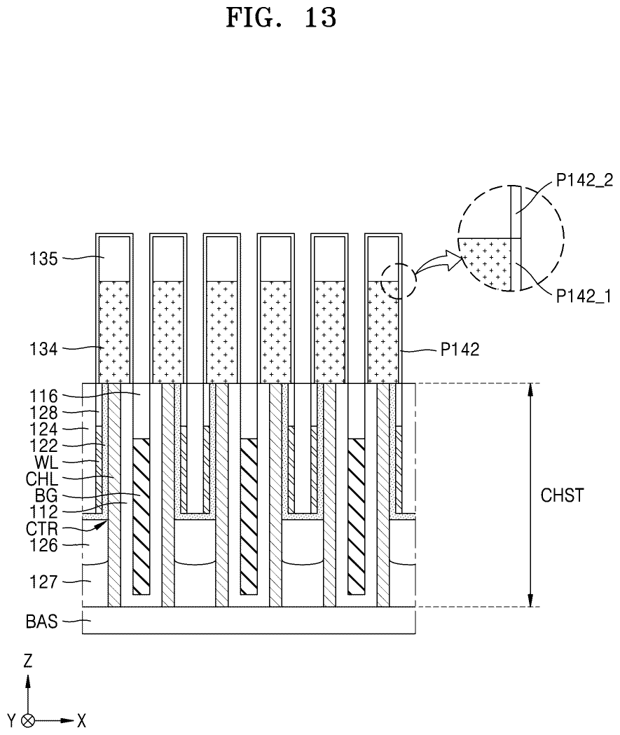

Referring to FIG. 13, a preliminary outer spacer P142 may be formed on the resulting structure of FIG. 12. The preliminary outer spacer P142 may be formed by performing nitridation on the surfaces of the plurality of first conductive patterns 134 and the plurality of contact plug sacrificial patterns 135. For example, the nitridation process of forming the preliminary outer spacer P142 may be performed by utilizing plasma. When forming the preliminary outer spacer P142, some exposed portions of the upper surface of the channel structure CHST are not subjected to nitridation, and thus, the preliminary outer spacer P142 may be formed on the sidewalls of the plurality of first conductive patterns 134 and the sidewalls and upper surfaces of the plurality of contact plug sacrificial patterns 135.

Since the plurality of first conductive patterns 134 include a doped polysilicon layer or include both an undoped polysilicon layer and a doped polysilicon layer, a first preliminary section P142_1 of the preliminary outer spacer P142, which is formed by nitridation of the surfaces of the plurality of first conductive patterns 134, may include silicon nitride. Since the plurality of contact plug sacrificial patterns 135 include a silicon oxide layer, a second preliminary section P142_2 of the preliminary outer spacer P142, which is formed by nitridation of the surfaces of the plurality of contact plug sacrificial patterns 135, may include silicon oxynitride.

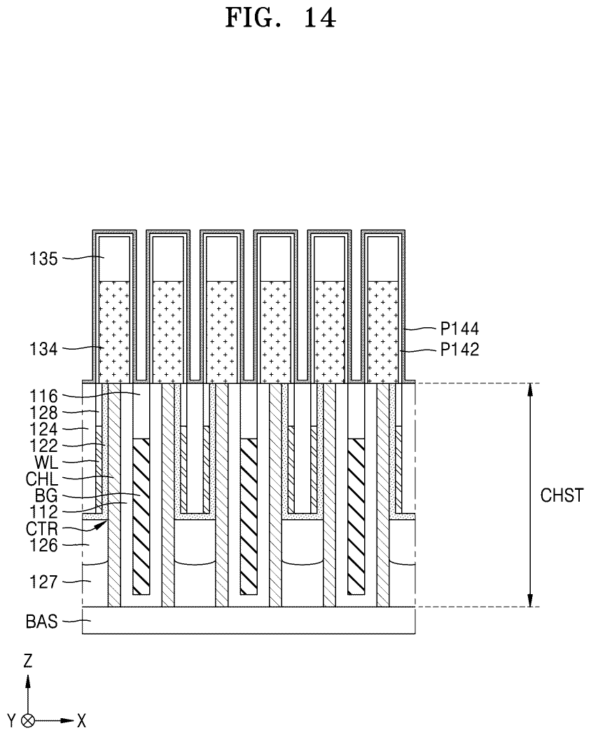

Referring to FIG. 14, a preliminary middle spacer P144 may be formed on the resulting structure of FIG. 13. The preliminary middle spacer P144 may cover the surface of the preliminary outer spacer P142 and may also cover some exposed portions of the upper surface of the channel structure CHST. The preliminary middle spacer P144 may be formed by using a chemical vapor deposition (CVD) process, a plasma enhanced chemical vapor deposition (PECVD) process, or an atomic layer deposition (ALD) process. The preliminary middle spacer P144 may include any one of silicon carbonitride, silicon oxynitride, silicon oxycarbonitride, and silicon nitride.

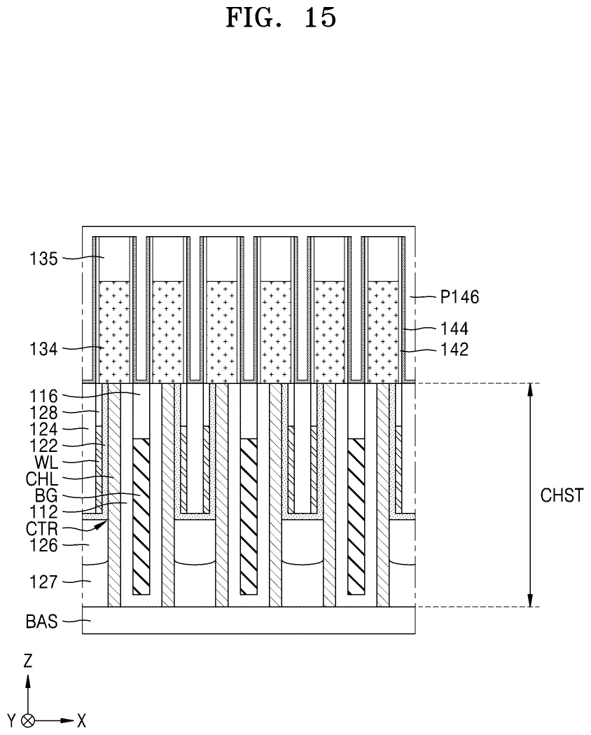

Referring to FIG. 15, a preliminary inner spacer P146 may be formed on the resulting structure of FIG. 14. The preliminary inner spacer P146 may be formed on the preliminary middle spacer P144 and may, together with the preliminary outer spacer P142 and the preliminary middle spacer P144, fill the space between the plurality of first conductive patterns 134 and the plurality of contact plug sacrificial patterns 135. The preliminary inner spacer P146 may include silicon nitride. In some embodiments, when both the preliminary middle spacer P144 and the preliminary inner spacer P146 include silicon nitride, the nitrogen content of the preliminary middle spacer P144 may be higher than that of the preliminary inner spacer P146.

In some embodiments, the process of forming the preliminary outer spacer P142 may be omitted, and only the preliminary middle spacer P144 and the preliminary inner spacer P146 may be formed. Accordingly, the structure shown in FIG. 6B may be obtained.

In some embodiments, the process of forming the preliminary middle spacer P144 may be omitted, and only the preliminary outer spacer P142 and the preliminary inner spacer P146 may be formed. Accordingly, the structure shown in FIG. 6C may be obtained.

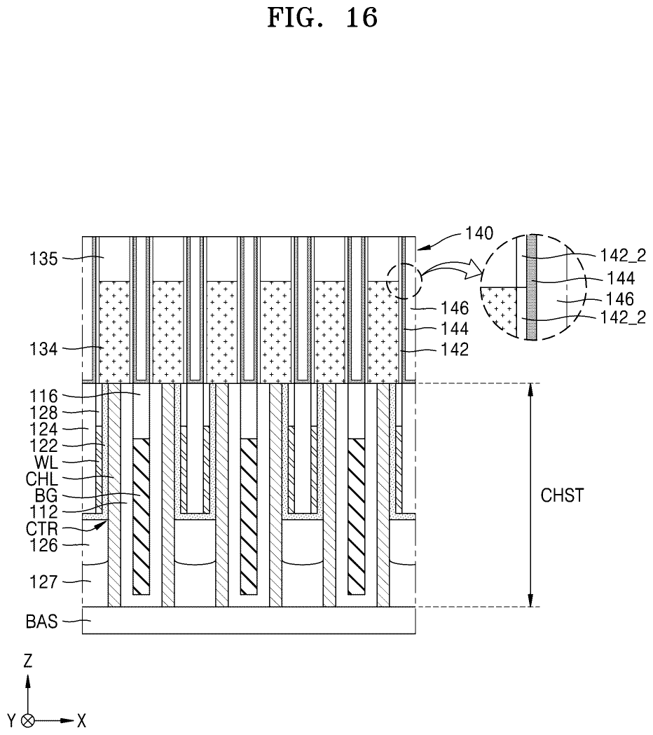

Referring to FIG. 16, an etch-back process may be performed on the resulting structure of FIG. 15 to form the outer spacer 142, the middle spacer 144, and the inner spacer 146. Due to the etch-back process, some portions of the preliminary outer spacer P142 (see FIG. 15), the preliminary middle spacer P144 (see FIG. 15), and the preliminary inner spacer P146 (see FIG. 15), which cover the upper surface of the contact plug sacrificial pattern 135, may be consumed. Some portions of the preliminary outer spacer P142 (see FIG. 15), the preliminary middle spacer P144 (see FIG. 15), and the preliminary inner spacer P146 (see FIG. 15), which cover the upper surface of the contact plug sacrificial pattern 135, may be consumed, and thus, the upper surface of the contact plug sacrificial pattern 135 may be exposed.

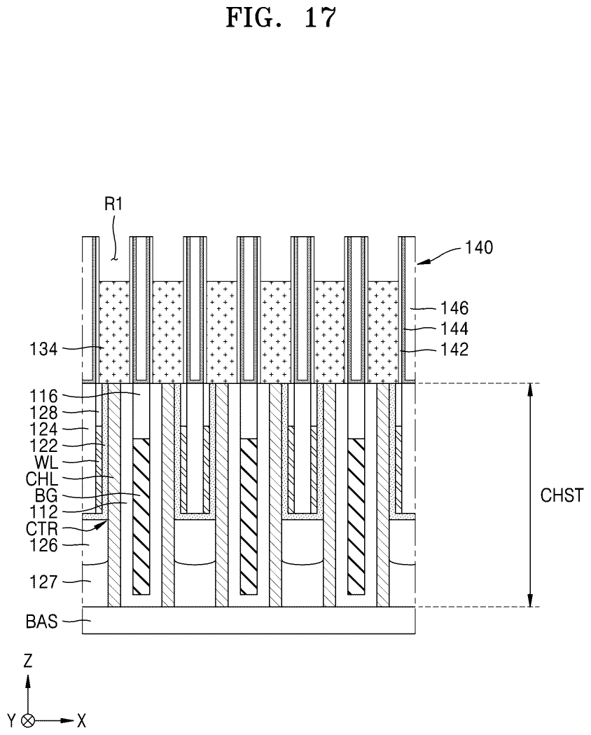

Referring to FIG. 17, an etching process may be performed to remove the contact plug sacrificial pattern 135 from the resulting structure of FIG. 16. An etchant may flow in via the upper surface of the exposed contact plug sacrificial pattern 135 and perform etching in a downward direction. Ultimately, the contact plug sacrificial pattern 135 may be completely removed, and a recess R1 may be formed. The etching process may be performed as a wet etching process, and the contact plug sacrificial pattern 135 may be selectively removed by the etching process. The etching process may be performed by using a hydrogen fluoride (HF)-based solution. For example, buffered oxide etch (BOE) or diluted HF (DHF) may be used.

In some embodiments, when the contact plug sacrificial pattern 135 is removed by the etching process, a portion of the outer spacer 142 may also be consumed. The outer spacer 142 are partially consumed together. In embodiments, a portion of the outer spacer 142, which covers the entire sidewall of the first conductive pattern 134, may be left, but a portion of the outer spacer 142, which covers the entire sidewalls of the second conductive pattern 136 and the third conductive pattern 138, may be consumed.

In embodiments, a portion of the outer spacer 142, which covers the lower portion of the sidewall of the first conductive pattern 134, may be left, but a portion of the outer spacer 142, which covers the upper portion of the sidewall of the first conductive pattern 134 and the entire sidewalls of the second conductive pattern 136 and the third conductive pattern 138, may be consumed.

In embodiments, a portion of the outer spacer 142, which covers the entire sidewall of the first conductive pattern 134 and lower portions of the sidewalls of the second conductive pattern 136 and third conductive pattern 138, may be left, but a portion of the outer spacer 142, which covers the upper portions of the sidewalls of the second conductive pattern 136 and third conductive pattern 138, may be consumed.

The etching process is performed as a wet etching process, which is an isotropic etching process. Accordingly, the upper end 142aE of the remaining outer spacer 142a may have a concave upper surface as shown in FIG. 6A. Also, the vertical length of a portion of the outer spacer 142a, adjacent to the sidewall 130S of the contact plug 130, may be different from the vertical length of a portion of the outer spacer 142a, distant from the sidewall 130S of the contact plug 130. For example, the vertical length of the outer spacer 142a may decrease towards the sidewall 130S of the contact plug 130.

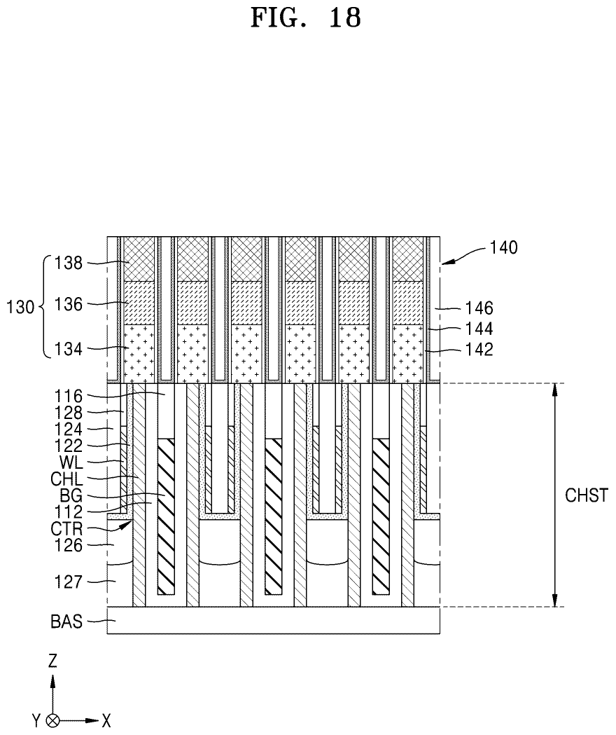

Referring to FIG. 18, the second conductive pattern 136 and the third conductive pattern 138 may be formed inside the recess R1 above the first conductive pattern 134 of FIG. 17. Specifically, when the third conductive pattern 138 including a metal layer is deposited on the first conductive pattern 134 and then heat-treated, an upper portion of the first conductive pattern 134 may be partially consumed to form the second conductive pattern 136 including a metal silicide layer.

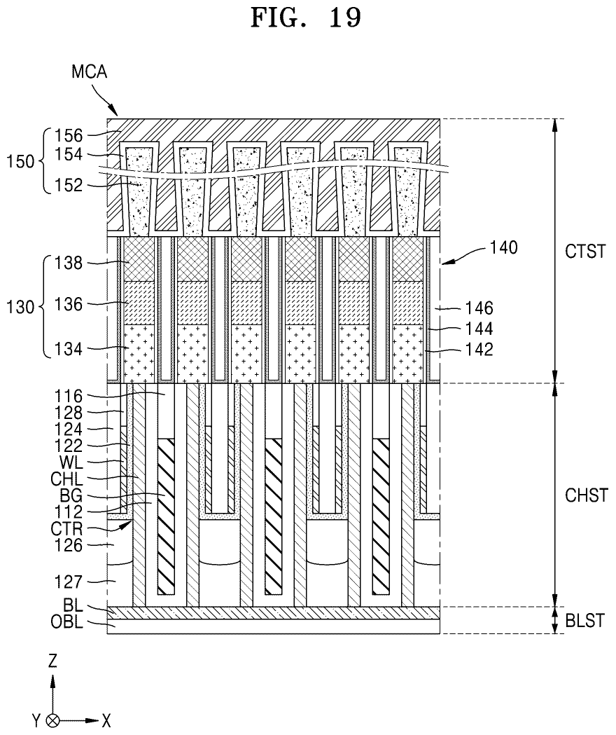

Referring to FIG. 19, the capacitor 150 may be formed on the contact plug 130 and the spacer structure 140 of FIG. 18. The plurality of lower electrodes 152 may be formed at positions corresponding to the plurality of contact plugs 130 so as to be electrically connected to the plurality of contact plugs 130, the capacitor dielectric layer 154 may cover the surfaces of the plurality of the lower electrodes 152, the upper surface of the exposed contact plug 130, and the upper surface of the exposed spacer structure 140, and the upper electrode 156 may be formed on the capacitor dielectric layer 154. Consequently, the capacitor structure CTST may be formed.

Subsequently, the base substrate BAS on the channel structure CHST may be removed, and the plurality of bit lines BL and the bit line insulating layer OBL for electrically isolating the plurality of bit lines BL from each other and covering surfaces of the plurality of bit lines BL may be formed above the channel structure CHST. Consequently, the memory cell array structure MCA may be formed.

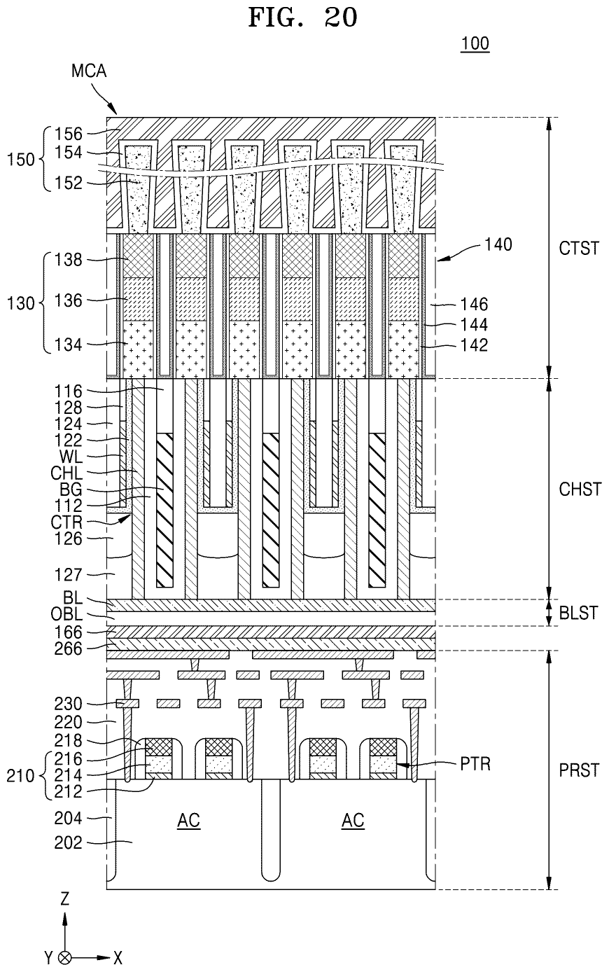

Referring to FIG. 20, the active region AC may be formed in the peripheral circuit substrate 202, and the peripheral circuit transistor PTR may be formed on the active region AC. For example, the peripheral circuit transistor PTR may include the circuit gate structure 210. Subsequently, the wiring structure 230 may be formed, and the inter-wiring insulating layer 220 may cover the plurality of circuit gate structures 210 and the wiring structure 230. Consequently, the peripheral circuit structure PRST may be formed.

Subsequently, the first bonding insulating layer 166 is formed on the bit line insulating layer OBL, and the second bonding insulating layer 266 is formed on the inter-wiring insulating layer 220. Then, the first bonding insulating layer 166 on the memory cell array structure MCA is positioned so as to face the second bonding insulating layer 266 on the peripheral circuit structure PRST. The first bonding insulating layer 166 may be coupled to the second bonding insulating layer 266, and thus, the peripheral circuit structure PRST may be bonded to the memory cell array structure MCA.

Consequently, the semiconductor device 100 may be manufactured.

In a comparative example, when the spacer structure includes only the inner spacer 146, an upper portion of the inner spacer 146 may also be partially consumed during the etching process of the contact plug sacrificial pattern 135. As a result, a sufficient distance between adjacent contact plugs 130 among the plurality of contact plugs 130 may not be formed in the upper portions of the plurality of contact plugs 130, and thus, bridges may occur between the plurality of contact plugs 130.

According to embodiments, the spacer structure 140 includes the outer spacer 142 and the middle spacer 144 in addition to the inner spacer 146, which may minimize the consumption of the upper portion of the inner spacer 146 during the etching process of the contact plug sacrificial pattern 135. Accordingly, the occurrence of bridges between the plurality of contact plugs 130 may be minimized to manufacture the semiconductor device having the improved operational reliability.

While the inventive concept has been particularly shown and described with reference to embodiments thereof, it will be understood that various changes in form and details may be made therein without departing from the spirit and scope of the following claims.

What is claimed is:

1. A semiconductor device comprising:
a bit line;
a channel layer on the bit line;
a contact plug disposed on the channel layer and electrically connected to the channel layer;
a spacer structure provided on a sidewall of the contact plug and surrounding the contact plug; and
a capacitor electrically connected to the contact plug,
wherein the spacer structure comprises a middle spacer and an inner spacer disposed sequentially on the sidewall of the contact plug,
the contact plug comprises:
a first conductive pattern comprising a semiconductor material;
a second conductive pattern disposed on the first conductive pattern and comprising a metal-based material; and
a third conductive pattern disposed on the second conductive pattern and comprising a metal-based material, and
the first conductive pattern is spaced apart from the inner spacer with the middle spacer therebetween.

2. The semiconductor device of claim 1, wherein the second conductive pattern and the third conductive pattern are spaced apart from the inner spacer with the middle spacer therebetween.

3. The semiconductor device of claim 2, wherein:
the spacer structure further comprises an outer spacer located between the sidewall of the contact plug and the middle spacer,
the first conductive pattern is spaced apart from the middle spacer with the outer spacer therebetween, and
the second conductive pattern and the third conductive pattern are in contact with the middle spacer.

4. The semiconductor device of claim 2, wherein:
the spacer structure further comprises an outer spacer located between the sidewall of the contact plug and the middle spacer, and
the first conductive pattern, the second conductive pattern, and the third conductive pattern are spaced apart from the middle spacer with the outer spacer therebetween.

5. The semiconductor device of claim 1, wherein the middle spacer comprises a same material as a material of the inner spacer and has a different composition ratio from that of the inner spacer.

6. The semiconductor device of claim 1, wherein:
the middle spacer and the inner spacer comprise silicon nitride, and
the middle spacer has a different composition ratio from that of the inner spacer.

7. The semiconductor device of claim 1, wherein the middle spacer comprises a different material from a material of the inner spacer.

8. The semiconductor device of claim 1, wherein:
the spacer structure further comprises an outer spacer located between the sidewall of the contact plug and the middle spacer,
the outer spacer comprises: a first sub-spacer disposed on the channel layer; and a second sub-spacer disposed on the first sub-spacer, and
the first sub-spacer comprises a different material from a material of the second sub-spacer.

9. The semiconductor device of claim 8, wherein:
the contact plug comprises the first conductive pattern, the second conductive pattern and the third conductive pattern, sequentially stacked on the channel layer,
the first sub-spacer covers a sidewall of the first conductive pattern, and
the second sub-spacer covers sidewalls of the second conductive pattern and the third conductive pattern.

10. The semiconductor device of claim 8, wherein:
the first sub-spacer does not comprise oxygen, and
the second sub-spacer comprises oxygen.

11. A semiconductor device comprising:
a bit line;
a channel layer on the bit line;
a contact plug disposed on the channel layer and electrically connected to the channel layer;
a spacer structure provided on a sidewall of the contact plug and surrounding the contact plug; and
a capacitor electrically connected to the contact plug,
wherein:
the spacer structure comprises an outer spacer, a middle spacer and an inner spacer, disposed sequentially on the sidewall of the contact plug,
the contact plug is spaced apart from the inner spacer with the outer spacer and the middle spacer therebetween, and
the outer spacer comprises:
a first sub-spacer disposed on the channel layer; and
a second sub-spacer disposed on the first sub-spacer, and
the first sub-spacer comprises a different material from a material of the second sub-spacer.

12. The semiconductor device of claim 11, wherein:
the first sub-spacer comprises a first element, and
the second sub-spacer comprises the first element and further comprises a second element different from the first element.

13. The semiconductor device of claim 11, wherein:
the first sub-spacer does not comprise oxygen, and
the second sub-spacer comprises oxygen.

14. The semiconductor device of claim 11, wherein:
the contact plug comprises a first conductive pattern, a second conductive pattern and a third conductive pattern, sequentially stacked in a vertical direction,
the first sub-spacer covers a sidewall of the first conductive pattern, and
the second sub-spacer covers sidewalls of the second conductive pattern and the third conductive pattern.

15. The semiconductor device of claim 14, wherein:
the first conductive pattern comprises a semiconductor material, and
the second conductive pattern and the third conductive pattern comprise a metal-based material.

16. The semiconductor device of claim 11, wherein the middle spacer comprises a same material as a material of the inner spacer but has a different composition ratio from that of the inner spacer, or the middle spacer comprises a different material from the material of the inner spacer.

17. A semiconductor device comprising:
a bit line extending in a first substantially horizontal direction;
a word line provided above the bit line and extending in a second substantially horizontal direction intersecting the first substantially horizontal direction;
a back gate line provided above the bit line, extending in the second substantially horizontal direction, and spaced apart from the word line in the first substantially horizontal direction;
a channel layer extending in a substantially vertical direction, and arranged between the word line and the back gate line such that the channel layer is adjacent to the word line and the back gate line in the first substantially horizontal direction;
a contact plug disposed on the channel layer and electrically connected to the channel layer; and
a spacer structure provided on a sidewall of the contact plug, and surrounding the contact plug in the first substantially horizontal direction,
wherein the spacer structure comprises an outer spacer, a middle spacer and an inner spacer, sequentially stacked on the sidewall of the contact plug in the first substantially horizontal direction.

18. The semiconductor device of claim 17, wherein the contact plug comprises:
a first conductive pattern comprising a semiconductor material;
a second conductive pattern disposed on the first conductive pattern and comprising a metal-based material; and
a third conductive pattern disposed on the second conductive pattern and comprising a metal-based material, wherein the third conductive pattern comprises a different material from a material of the second conductive pattern.

19. The semiconductor device of claim 18, wherein:
the outer spacer comprises a first sub-spacer and a second sub-spacer, sequentially stacked in the vertical direction,
the first sub-spacer covers the first conductive pattern, and
the second sub-spacer covers the second conductive pattern and the third conductive pattern.

20. The semiconductor device of claim 17, wherein:
the outer spacer comprises a first sub-spacer and a second sub-spacer, sequentially stacked in the vertical direction,
the first sub-spacer comprises silicon nitride,
the second sub-spacer comprises silicon oxynitride,
the middle spacer comprises any one of silicon carbonitride, silicon oxynitride, silicon oxycarbonitride, and silicon nitride, and
the inner spacer comprises silicon nitride.
